(19) United States
(12) Patent Application Publication
(10) Pub. No.: US 2024/0006315 A1
(43) Pub. Date: Jan. 4, 2024

(54) SELF-ALIGNED BACKSIDE GATE CONTACT FOR BACKSIDE SIGNAL LINE INTEGRATION

(71) Applicant: International Business Machines Corporation, Armonk, NY (US)

(72) Inventors: Ruilong Xie, Niskayuna, NY (US); REINALDO VEGA, Mahopac, NY (US); David Wolpert, Poughkeepsie, NY (US); Kisik Choi, Watervliet, NY (US)

(21) Appl. No.: 17/854,305

(22) Filed: Jun. 30, 2022

(51) Int. Cl. H01L 23/528; H01L 23/535; H01L 23/498; H01L 21/8238; H01L 21/768

(52) U.S. Cl. CPC H01L 23/5286; H01L 23/535; H01L 23/49822; H01L 21/823871; H01L 21/76898

(57) ABSTRACT

A semiconductor array structure includes a substrate; a plurality of field effect transistors (FETs) arranged in rows and located on the substrate, each comprising a first source-drain region, a second source-drain region, at least one channel coupling the source-drain regions, and a gate adjacent the at least one channel. A plurality of frontside signal lines are on a front side of the FETs; a plurality of backside power rails are on a back side of the FETs; a plurality of backside signal wires are on the back side. Frontside signal connections run from the frontside signal lines to the first source-drain regions; Power connections run from the backside power rails to the second source-drain regions; and backside gate contact connections run from the backside signal wires to the gates. The backside gate contact connections each have a bottom dimension larger than the gate length.

### BACKGROUND

The present invention relates generally to the electrical, electronic and computer arts and, more particularly, to signal lines in integrated circuits (ICs).

In integrated circuit technology, the power delivery network of a chip provides power and reference voltage to the active devices; the power delivery network is separate from the signal network. Traditionally, both power delivery and signal networks are fabricated on the front side of the wafer through back-end-of-line (BEOL) processing. Various proposals have been made to provide power distribution on the backside of the silicon wafer, potentially allowing, for example, direct power delivery, enhanced system performance, increased chip area utilization, and reduced BEOL complexity.

Heretofore, provision of additional networks on the backside of the chip has been limited to power rather than signals.

### BRIEF SUMMARY

Principles of the invention provide techniques for self-aligned backside gate contact(s) for backside signal line integration. In one aspect, an exemplary semiconductor structure includes a backside power rail; a backside signal line; a frontside signal line; a first source-drain region; a second source-drain region; at least one channel coupling the first and second source-drain regions; a gate adjacent the at least one channel; a frontside signal connection from the frontside signal line to the first source-drain region; a power connection from the backside power rail to the second source-drain region; and a backside gate contact from the gate to the backside signal line.

In a further aspect, an exemplary semiconductor array structure includes a substrate; a plurality of field effect transistors located on the substrate, each comprising a first source-drain region, a second source-drain region, at least one channel coupling the first and second source-drain regions, and a gate, having a gate length, and being adjacent to the at least one channel, the plurality of field effect transistors being arranged in rows; a plurality of frontside signal lines on a front side of the plurality of field effect transistors; a plurality of backside power rails on a back side of the plurality of field effect transistors; and a plurality of backside signal wires on the back side of the plurality of field effect transistors. A plurality of frontside signal connections run from the plurality of frontside signal lines to the first source-drain regions; a plurality of power connections run from the backside power rails to the second source-drain regions; and a plurality of backside gate contact connections run from the backside signal wires to the gates. The backside gate contact connections each have a bottom dimension larger than the gate length.

In another aspect, a hardware description language (HDL) design structure is encoded on a machine-readable data storage medium, and the HDL design structure includes elements that when processed in a computer-aided design system generates a machine-executable representation of an apparatus/circuit. The HDL design structure includes a semiconductor structure or semiconductor array structure as just described.

In still another aspect, an exemplary method of forming a semiconductor structure includes defining n-type and p-type active regions in a nanosheet stack on a substrate and forming shallow trench isolation (STI) regions between the active regions; forming backside gate contact vias in the shallow trench isolation (STI) regions in spaces between the n-type and p-type active regions; forming dummy gates and gate spacers, such that bottom portions of the backside gate contact vias are filled with dummy gate material of the dummy gates; removing the dummy gates and forming replacement high-K metal gates such that the backside gate contact vias are filled with high-K metal gate material of the high-K metal gates adjacent bottoms of the gates, to obtain a resultant structure; on a frontside of the resultant structure opposite the substrate, forming back end of line wiring; and forming backside signal lines connecting to the high-K metal gate material in the backside gate contact vias.

In yet another aspect, another exemplary method of forming a semiconductor structure includes defining n-type and p-type active regions in a nanosheet stack on a substrate and forming shallow trench isolation (STI) regions between the active regions; forming backside gate contact vias in the shallow trench isolation (STI) regions in spaces between the n-type and p-type active regions; filling the backside gate contact vias with sacrificial backside gate contact material and recessing the sacrificial backside gate contact material; forming dummy gates and gate spacers, such that bottom portions of the backside gate contact vias are filled with the sacrificial backside gate contact material in contact with dummy gate material of the dummy gates; removing the dummy gates and forming replacement high-K metal gates such that the bottom portions of the backside gate contact vias are filled with the sacrificial backside gate contact material in contact with high-K metal gate material of the high-K metal gates, to obtain a resultant structure; on a frontside of the resultant structure opposite the substrate, forming back end of line wiring; removing the sacrificial backside gate contact material to form voids; and forming backside signal lines connecting to the high-K metal gate material through the voids.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
enhanced system performance for integrated circuits
increased chip area utilization for integrated circuits
reduced BEOL complexity for integrated circuits

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 shows a high-level layout (top view) of an exemplary semiconductor structure, according to an aspect of the invention.

FIG. 2A shows a top view of an exemplary completed semiconductor structure, according to an aspect of the invention.

FIG. 2B is a cross section of a starting wafer structure taken along cutting plane line Y (along gate) in FIG. 2A.

FIG. 3 is a cross section of the structure of FIG. 2B, taken along cutting plane line Y in FIG. 2A, after nanosheet patterning.

FIG. 4 is a cross section of the structure of FIG. 3, taken along cutting plane line Y (along the gate) in FIG. 2A, after deposition of shallow trench isolation (STI) material and removal of the hard mask.

FIG. 5A is a view similar to FIG. 2A, with additional cutting plane lines, and with details of a via, according to an aspect of the invention.

FIG. 5B is a cross section of the structure of FIG. 4 after backside gate contact patterning and suitable etching such as reactive ion etching (RIE), taken along cutting plane line Y1 in FIG. 5A, according to an aspect of the invention.

FIG. 5C is a cross section of the exemplary structure of FIG. 4 after backside gate contact patterning and suitable etching such as reactive ion etching (RIE), taken along cutting plane line X2 in FIG. 5A, according to an aspect of the invention.

FIGS. 6A, 6B, 6C, and 6D are cross sections of the exemplary structure of FIGS. 5B and 5C, after formation of dummy gates and deposition of gate hard mask material, taken respectively along cutting plane lines X1, X2, Y1, and Y2 in FIG. 5A, according to an aspect of the invention.

FIGS. 7A, 7B, 7C, and 7D are cross sections of the exemplary structure of FIGS. 6A, 6B, 6C, and 6D, after lithographic patterning of the gate hard mask material followed by suitable etching, such as reactive ion etching (RIE), of the dummy gate material, taken respectively along cutting plane lines X1, X2, Y1, and Y2 in FIG. 5A, according to an aspect of the invention.

FIGS. 8A, 8B, 8C, and 8D are cross sections of the exemplary structure of FIGS. 7A, 7B, 7C, and 7D, after formation of gate spacer, recessing of the nanosheets, formation of inner spacers, and epitaxial growth of p-type source-drain regions and n-type source-drain regions, taken respectively along cutting plane lines X1, X2, Y1, and Y2 in FIG. 5A, according to an aspect of the invention.

FIGS. 9A, 9B, 9C, and 9D are cross sections of the exemplary structure of FIGS. 8A, 8B, 8C, and 8D, after interlayer dielectric (ILD) fill, chemical-mechanical polishing (CMP), gate cut, dummy gate and SiGe removal, and replacement high-K metal gate (HKMG) formation, taken respectively along cutting plane lines X1, X2, Y1, and Y2 in FIG. 5A, according to an aspect of the invention.

FIGS. 10A, 10B, 10C, and 10D are cross sections of the exemplary structure of FIGS. 9A, 9B, 9C, and 9D, after forming middle of line (MOL) contacts, back end of line (BEOL) interconnect(s), and carrier wafer bonding, taken respectively along cutting plane lines X1, X2, Y1, and Y2 in FIG. 5A, according to an aspect of the invention.

FIGS. 11A, 111B, 11C, and 11D are cross sections of the exemplary structure of FIGS. 10A, 10B, 10C, and 10D, after inversion or “flipping,” taken respectively along cutting plane lines X1, X2, Y1, and Y2 in FIG. 5A, according to an aspect of the invention.

FIGS. 12A, 12B, 12C, and 12D are cross sections of the exemplary structure of FIGS. 11A, 111B, 11C, and 11D, after removal of the substrate, stopping on the etch stop layer, taken respectively along cutting plane lines X1, X2, Y1, and Y2 in FIG. 5A, according to an aspect of the invention.

FIGS. 13A, 13B, 13C, and 13D are cross sections of the exemplary structure of FIGS. 12A, 12B, 12C, and 12D, after removal of the etch stop layer, taken respectively along cutting plane lines X1, X2, Y1, and Y2 in FIG. 5A, according to an aspect of the invention.

FIGS. 14A, 14B, 14C, and 14D are cross sections of the exemplary structure of FIGS. 13A, 13B, 13C, and 13D, after recessing the silicon substrate, taken respectively along cutting plane lines X1, X2, Y1, and Y2 in FIG. 5A, according to an aspect of the invention.

FIGS. 15A, 15B, 15C, and 15D are cross sections of the exemplary structure of FIGS. 14A, 14B, 14C, and 14D, after deposition of backside inter-layer dielectric (ILD), taken respectively along cutting plane lines X1, X2, Y1, and Y2 in FIG. 5A, according to an aspect of the invention.

FIGS. 16A, 16B, 16C, and 16D are cross sections of the exemplary structure of FIGS. 15A, 15B, 15C, and 15D, after forming backside power rails and signal lines, taken respectively along cutting plane lines X1, X2, Y1, and Y2 in FIG. 5A, according to an aspect of the invention.

FIGS. 17A, 17B, 17C, and 17D are cross sections of the exemplary structure of FIGS. 16A, 16B, 16C, and 16D, after forming backside interconnects, taken respectively along cutting plane lines X1, X2, Y1, and Y2 in FIG. 5A, according to an aspect of the invention.

FIGS. 18A and 18B are cross sections of the exemplary structure of FIGS. 5B and 5C, after filling trenches with a sacrificial backside gate contact material and recessing same, taken respectively along cutting plane lines Y1 and X2 in FIG. 5A, according to another aspect of the invention.

FIGS. 19A, 19B, 19C, and 19D are cross sections of the exemplary inventive structure of FIGS. 18A and 18B, after formation of a dummy gate, deposition of gate hard mask material, reactive ion etching (RIE) of the dummy gate material, deposition of gate spacers, recessing of the nanosheets, formation of inner spacers, and epitaxial growth of p-type source-drain regions and n-type source-drain regions, taken respectively along cutting plane lines X1, X2, Y1, and Y2 in FIG. 5A.

FIGS. 20A, 20B, 20C, and 20D are cross sections of the exemplary inventive structure of FIGS. 19A, 19B, 19C, and 19D, after processes analogous to those shown in FIGS. 9A-15D, including deposition of backside ILD, taken respectively along cutting plane lines X1, X2, Y1, and Y2 in FIG. 5A.

FIGS. 21A, 21B, 21C, and 21D are cross sections of the exemplary inventive structure of FIGS. 20A, 20B, 20C, and 20D, after patterning and etching of the backside ILD, taken respectively along cutting plane lines X1, X2, Y1, and Y2 in FIG. 5A.

FIGS. 22A, 22B, 22C, and 22D are cross sections of the exemplary inventive structure of FIGS. 21A, 21B, 21C, and 21D, after selective removal of sacrificial backside gate contact material and exposed HfO₂ removal, taken respectively along cutting plane lines X1, X2, Y1, and Y2 in FIG. 5A.

FIGS. 23A, 23B, 23C, and 23D are cross sections of the exemplary inventive structure of FIGS. 22A, 22B, 22C, and 22D, after formation of backside power rails and signal lines, taken respectively along cutting plane lines X1, X2, Y1, and Y2 in FIG. 5A.′

FIG. 24 shows exemplary signal and power connections, in accordance with aspects of the inventions.

FIG. 25 shows a schematic of backside interconnects, in accordance with aspects of the inventions.

FIG. 26 depicts a computer system that could implement a design process such as that shown in FIG. 27).

FIG. 27 is a flow diagram of a design process used in semiconductor design, manufacture, and/or test.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

As noted, various proposals have been made to provide power distribution on the backside of the silicon wafer, potentially allowing, for example, direct power delivery, enhanced system performance, increased chip area utilization, and reduced BEOL complexity. Currently proposed techniques deliver power to the source/drain (S/D) regions of field effect transistors (FETs), but do not provide any connections to the gates of the FETs. Advantageously, one or more embodiments add backside gate connection(s); for example, to provide a clock signal track. Heretofore, power vias have been provided to connect S/D epitaxy to a backside power distribution network (BSPDN). One or more embodiments provide both power vias for S/D epitaxy to power connection, and gate to backside signal line connection.

For example, in one or more embodiments, a semiconductor device includes at least a power via contact connecting S/D epitaxy to a backside power rail, and a signal line contact via connecting FET gates to a backside clock signal. In some cases, the signal line contact has a bottom dimension larger than the gate and is capped with a gate spacer. In some cases, the signal contact is a T-shaped structure at the bottom of the gate. In some cases, the power via contact and backside power rail are located within the N2N and P2P space(s). In some cases, the signal line contact and backside clock signal are located within the N2P space(s). Note that “N2N” refers to spaces between adjacent n-type FETs (NFETs); “P2P” refers to spaces between adjacent p-type FETs (PFETs); and “N2P” refers to spaces between adjacent NFETs and PFETs. In one or more embodiments, the signal line contact is filled with a high-K metal gate (HKMG).

In one or more exemplary embodiments, an exemplary process flow includes defining an active region and forming shallow trench isolation (STI); forming backside gate contact vias in the STI region between the N2P space(s); and forming a dummy gate and gate spacer, such that the bottom portion of the backside gate contact vias are filled with dummy gate material. In the end structure, the bottom portion of the backside gate contact vias that are filled with dummy gate material will eventually be filled with HKMG material as discussed below and the resulting region will be isolated from the FEOL structures by the gate spacers. In one or more exemplary embodiments, the exemplary process flow further includes: removing the dummy gate and forming a replacement high-k metal gate (HKMG) such that the backside gate contact via is also filled with the HKMG attached to the bottom of the gate; flipping the wafer; and forming backside signal lines connecting to the backside gate contact via.

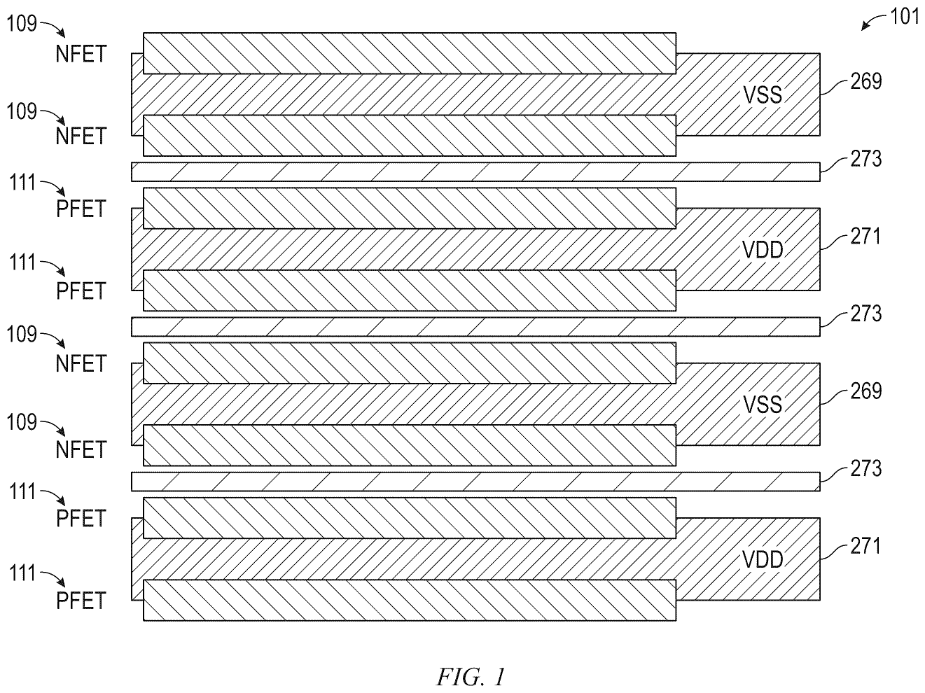

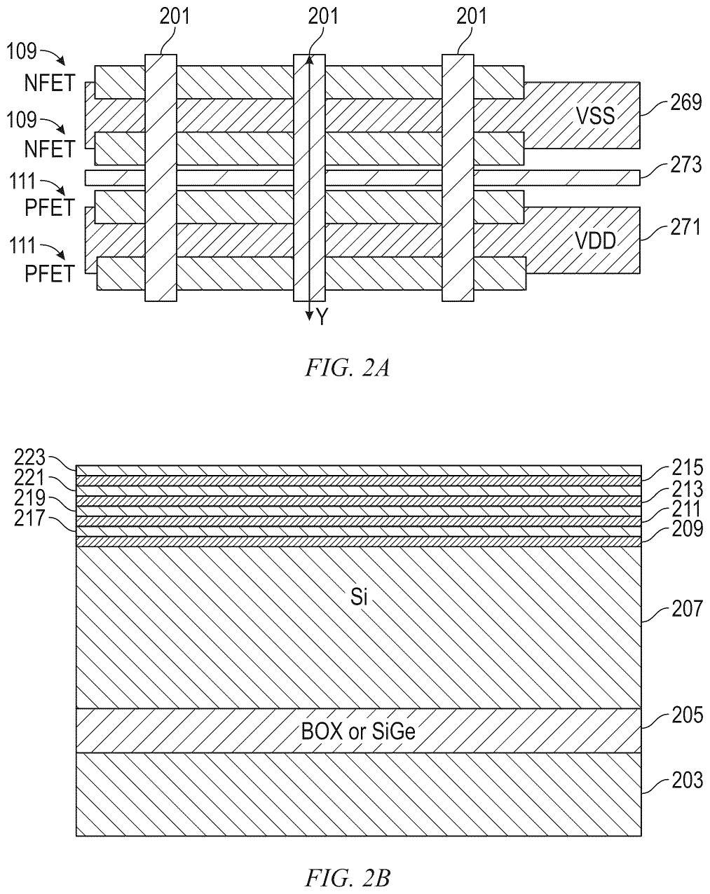

FIG. 1 shows a high-level layout (top view) of an exemplary semiconductor structure 101, according to an aspect of the invention. Note the backside power rails (e.g., VSS (e.g., ground voltage) 269, VDD (e.g., positive supply voltage) 271) and signal lines (e.g., clock signal 273). Note also the NFET regions 109 and PFET regions 111, depicted schematically. As discussed above, the spaces between NFETs 109 are referred to as N2N spaces; the spaces between PFETs 111 are referred to as P2P spaces; and the spaces between NFETs 109 and PFETs 111 are referred to as N2P spaces. Under the N2N and P2P spaces, note the respective backside power rails (VSS 269, VDD 271) connected to the S/D epitaxy, while under the N2P space note the backside clock signal 273 connected to the gates 201 (seen in FIG. 2A discussed below).

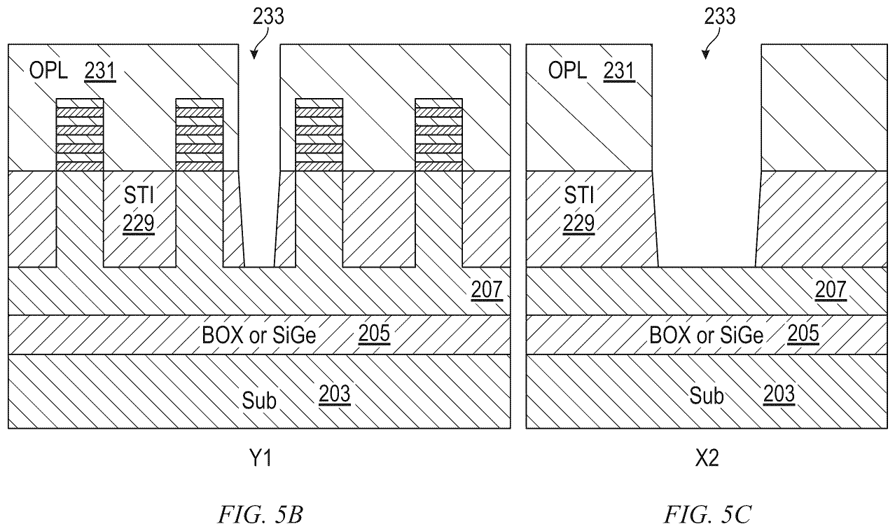

Consider now a first exemplary process flow, according to an aspect of the invention, and refer now to FIGS. 2A and 2B. FIG. 2B is a cross section of a starting wafer structure taken along cutting plane line Y (along gate) in FIG. 2A. Elements in FIG. 2A similar to those in FIG. 1 have the same reference character. FIGS. 2A and 5A (discussed below) are top views, of completed structures, with cutting plane lines for reference. Note the gates 201. The starting wafer structure includes a lower silicon portion 203, an intermediate etch stop portion 205 of (for example) buried oxide (BOX) or silicon germanium (SiGe), and an upper silicon portion 207. Outward of the upper silicon portion is a nanosheet structure including alternating layers of SiGe 209, 211, 213, 215 and silicon nanosheets 217, 219, 221, 223. The SiGe regions 209, 211, 213, 215 (and 205, if made of SiGe) can include, for example, SiGe with the Ge % ranging from 15-75%. The skilled artisan will be generally familiar with formation of nanosheet transistors.

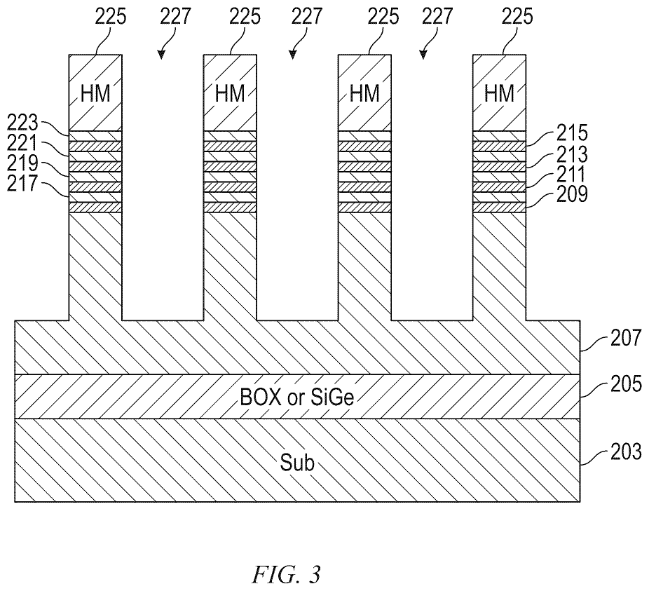

FIG. 3 is a cross section of the structure of FIG. 2B, taken along cutting plane line Y in FIG. 2A, after nanosheet patterning. In particular, hard mask 225 (e.g., layer or multi layers of dielectrics) is deposited, lithography is employed to create gaps in the hard mask, and etching is carried out to create trenches 227 corresponding to the gaps in the hard mask (the regions under the remaining hard mask 225 are not etched). The skilled artisan will be generally familiar with patterning hard masks via lithographic techniques and etching nanosheet structures.

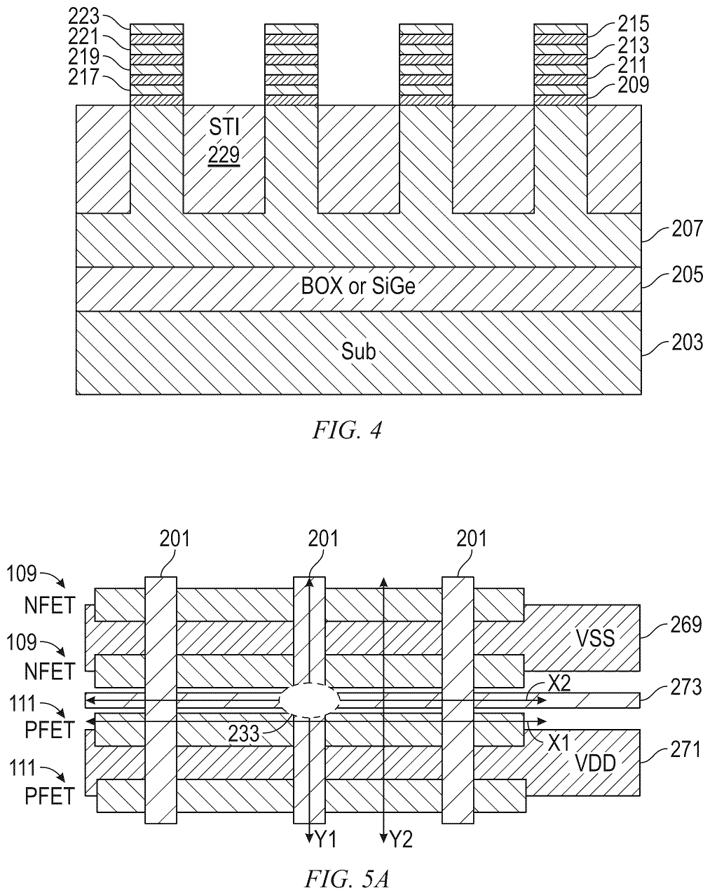

FIG. 4 is a cross section of the structure of FIG. 3, taken along cutting plane line Y (along the gate) in FIG. 2A, after deposition of shallow trench isolation (STI) material 229 (e.g., SiO or other suitable oxide; a suitable liner can be deposited first if desired, using known techniques and materials) and removal of the hard mask 225 (hard mask can be stripped using known techniques and materials). The STI can be deposited, for example, via Furnace Chemical Vapor Deposition (FCVD) or other suitable techniques.

Refer now to FIGS. 5A, 5B, and 5C. FIG. 5B is a cross section of a structure taken along cutting plane line Y1 in FIG. 5A. The alternating layers of SiGe 209, 211, 213, 215 and silicon nanosheets 217, 219, 221, 223 are not numbered in FIGS. 5B-17B to avoid clutter. Elements in FIG. 5A similar to those in FIG. 1 and FIG. 2A have the same reference character. FIG. 5C is a cross section of a structure taken along cutting plane line X2 in FIG. 5A. FIGS. 5B and 5C depict the structure of FIG. 4 after backside gate contact patterning and suitable etching such as reactive ion etching (RIE). Note the organic planarization layer (OPL) 231 and the vias 233 that are formed in the STI 229 under corresponding openings in the OPL 231. Any suitable type of OPL can be employed. The skilled artisan will be familiar with deposition and stripping of OPL, the patterning of same using lithographic techniques, and the formation of corresponding vias in STI material. Note generally that cutting plane lines X1 and X2 are cross-gate while cutting plane line Y1 is along-gate and cutting plane line Y2 is parallel to the gates between two adjacent gates.

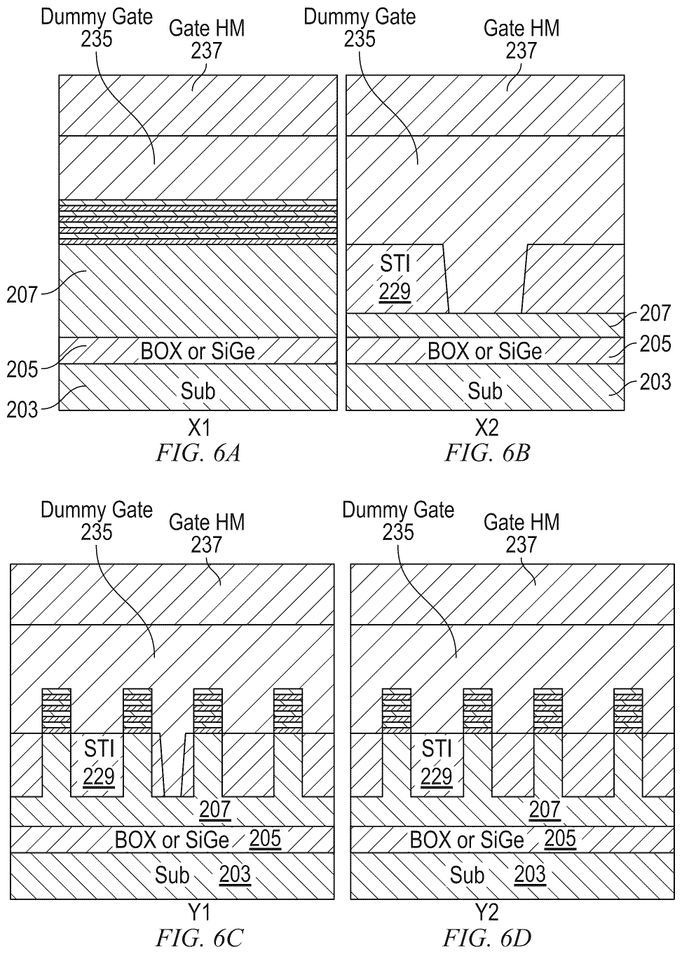

Refer now to FIGS. 6A, 6B, 6C, and 6D. FIG. 6A is a cross section of a structure taken along cutting plane line X1 in FIG. 5A. FIG. 6B is a cross section of a structure taken along cutting plane line X2 in FIG. 5A. FIG. 6C is a cross section of a structure taken along cutting plane line Y1 in FIG. 5A. FIG. 6D is a cross section of a structure taken along cutting plane line Y2 in FIG. 5A. FIGS. 6A-6D depict the structure of FIGS. 5B and 5C after formation of a dummy gate 235 and deposition of gate hard mask material 237. Note that the dummy gate is shown as a unitary structure to avoid clutter, but can include, e.g., a thin SiO₂ liner plus amorphous silicon (a-Si) in a known manner. For example, after thin liner deposition, deposit amorphous Si material and carry out planarization; and deposit gate hardmask material 237 (can be, e.g., a multilayer dielectric). The skilled artisan will have general familiarity with the dummy gate process.

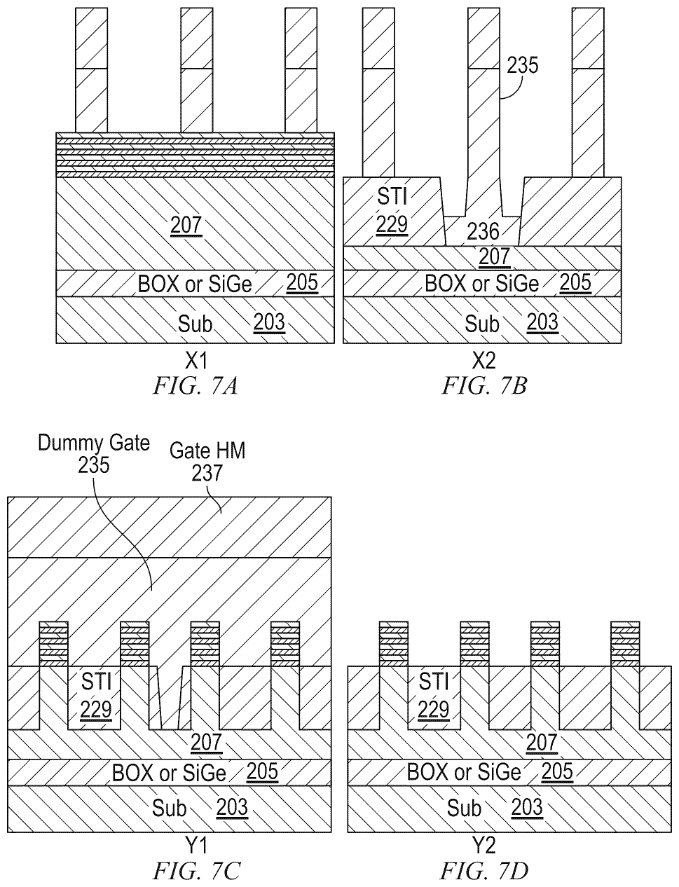

Refer now to FIGS. 7A, 7B, 7C, and 7D. FIG. 7A is a cross section of a structure taken along cutting plane line X1 in FIG. 5A. FIG. 7B is a cross section of a structure taken along cutting plane line X2 in FIG. 5A. FIG. 7C is a cross section of a structure taken along cutting plane line Y1 in FIG. 5A. FIG. 7D is a cross section of a structure taken along cutting plane line Y2 in FIG. 5A. FIGS. 7A-7D depict the structure of FIGS. 6A-6D after lithographic patterning of the gate hard mask material 237 followed by suitable etching, such as reactive ion etching (RIE), of the dummy gate material. This forms various gaps (not separately numbered) that will later contain inter-layer dielectric (ILD), epitaxially grown source-drain regions, and contacts, as will be apparent from the description that follows. For example, pattern the hardmask and etch the a-Si to form the dummy gates 235. The skilled artisan is familiar with techniques for lithographic patterning and etching.

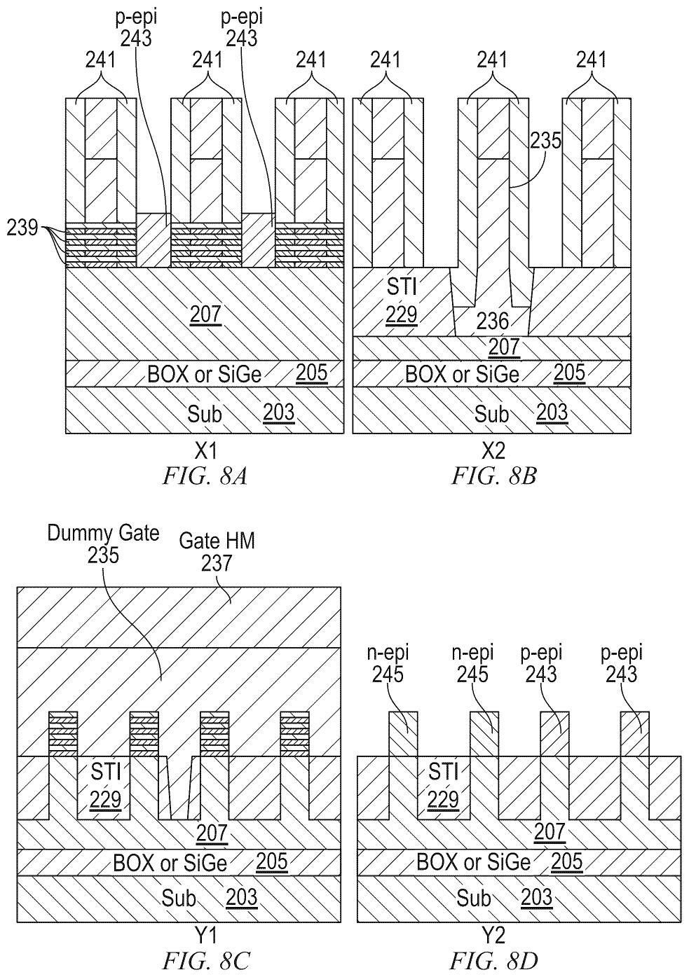

Refer now to FIGS. 8A, 8B, 8C, and 8D. FIG. 8A is a cross section of a structure taken along cutting plane line X1 in FIG. 5A. FIG. 8B is a cross section of a structure taken along cutting plane line X2 in FIG. 5A. FIG. 8C is a cross section of a structure taken along cutting plane line Y1 in FIG. 5A. FIG. 8D is a cross section of a structure taken along cutting plane line Y2 in FIG. 5A. FIGS. 8A-8D depict the structure of FIGS. 7A-7D after formation of gate spacer 241, recessing of the nanosheets, formation of inner spacers 239, and epitaxial growth of p-type source-drain regions 243 and n-type source-drain regions 245. The SiGe 209, 211, 213, 215 is laterally etched back (for example, use a gas phase HCl process for this aspect) and the inner spacers 239 are filled into the resulting areas. The skilled artisan is familiar with techniques for subsequent epitaxial growth of p-type and n-type source/drain regions and deposition of gate spacers 241. Suitable materials for the gate spacers 241 include a dielectric material such as silicon oxide, silicon nitride, or silicon oxynitride, which can be deposited in a known manner. A non-limiting example of material for the inner spacers 239 is SiN, spacers 239 can be formed in a known manner.

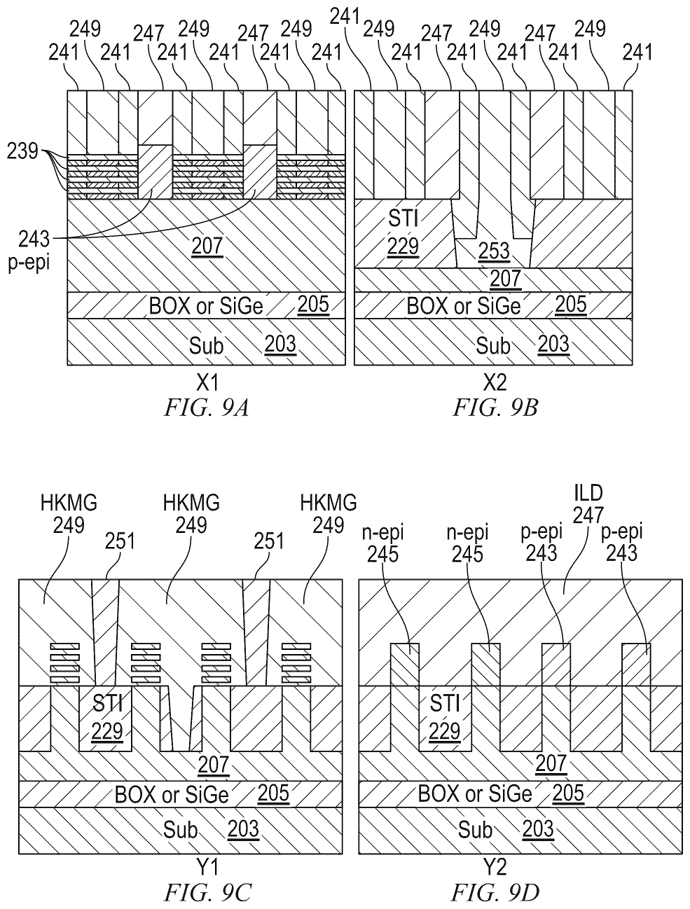

Refer now to FIGS. 9A, 9B, 9C, and 9D. FIG. 9A is a cross section of a structure taken along cutting plane line X1 in FIG. 5A. FIG. 9B is a cross section of a structure taken along cutting plane line X2 in FIG. 5A. FIG. 9C is a cross section of a structure taken along cutting plane line Y1 in FIG. 5A. FIG. 9D is a cross section of a structure taken along cutting plane line Y2 in FIG. 5A. FIGS. 9A-9D depict the structure of FIGS. 8A-8D after interlayer dielectric (ILD) fill, chemical-mechanical polishing (CMP), gate cut, dummy gate and SiGe removal, and replacement HKMG formation. Note the ILD 247 (e.g., FCVD SiO₂; generally, exemplary materials for the ILD layer(s) include SiOₓ, low-k oxide (with dielectric constant <3.9), SiN, or combinations of those materials (e.g., SiN and SiO₂)); HKMG material 249; and gate cuts 251. As seen at 253, the backside gate contact (portion of material 249) is self-aligned to the middle gate (referring back to the dummy gate RIE shown in FIGS. 7A-7D, even if the gate is misaligned to the left or the right, the backside gate contact is connected to the bottom of the gate). To move from the structure of FIGS. 8A-8D to the structure of FIGS. 9A-9D, selectively remove the sacrificial a-Si portion of the dummy gate 235 and sacrificial nanosheets 209, 211, 213, 215; form conformal High-K metal gate stacks; pattern and etch cavities for the gate cuts 251; and fill the cavities with dielectric material (e.g., similar to other suitable dielectric materials discussed herein) to form the gate cuts 251. In one or more embodiments, the gate stacks are high-k metal gate (HKMG) stacks. HKMGs include a high-k dielectric layer in combination with a metal gate feature. The high-k dielectric layer may include, as just a few non-limiting examples, hafnium silicon oxide, zirconium silicon oxide, hafnium oxide, or zirconium oxide. The metal gate feature may include, again, as just a few non-limiting examples, a work-function-tunable material such as titanium nitride, titanium aluminum nitride, titanium silicon nitride, tantalum nitride, tantalum aluminum nitride, or tantalum silicon nitride. The components of the HKMGs may, in one or more embodiments, be deposited by atomic layer deposition (ALD), chemical vapor deposition (CVD), or some combination of those two processes. The term “high-K” has a definite meaning to the skilled artisan in the context of high-K metal gate (HKMG) stacks and is not a mere relative term.

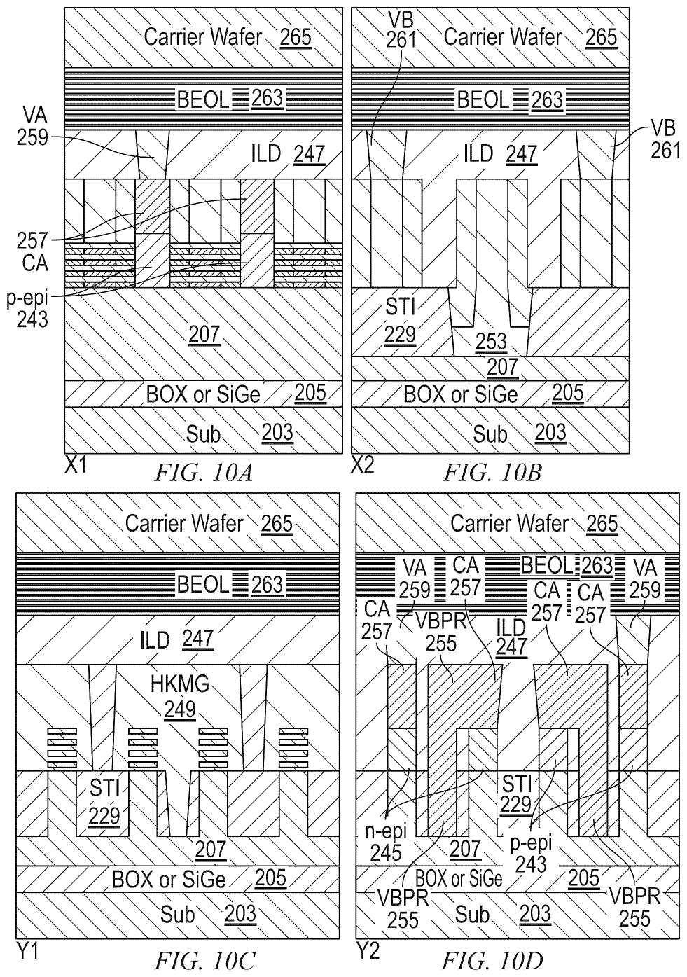

Refer now to FIGS. 10A, 10B, 10C, and 10D. FIG. 10A is a cross section of a structure taken along cutting plane line X1 in FIG. 5A. FIG. 10B is a cross section of a structure taken along cutting plane line X2 in FIG. 5A. FIG. 10C is a cross section of a structure taken along cutting plane line Y1 in FIG. 5A. FIG. 10D is a cross section of a structure taken along cutting plane line Y2 in FIG. 5A. FIGS. 10A-10D depict the structure of FIGS. 9A-9D after forming middle of line (MOL) contacts, back end of line (BEOL) interconnect(s), and carrier wafer bonding. Note the VBPR (via for connection to backside power rail) 255, source/drain contact (CA) 257, VA (via connecting source-drain contact to BEOL wiring) 259, VB (via connecting gate to BEOL wiring) 261, BEOL wiring 263, and carrier wafer 265. The skilled artisan will be familiar with conventional MOL and BEOL processing and wafer bonding techniques. Traditionally, BEOL refers to the interconnects, contacts, vias, and dielectric layers that wire the active devices into specific circuit configurations. More recently introduced middle-of-the-line (MOL) interconnects help reduce congestion for local routes. MOL typically sits below the first metal layer. in FIGS. 10A-10D, elements 255, 257 can be considered as MOL while elements 259, 261, 263 can be considered as BEOL.

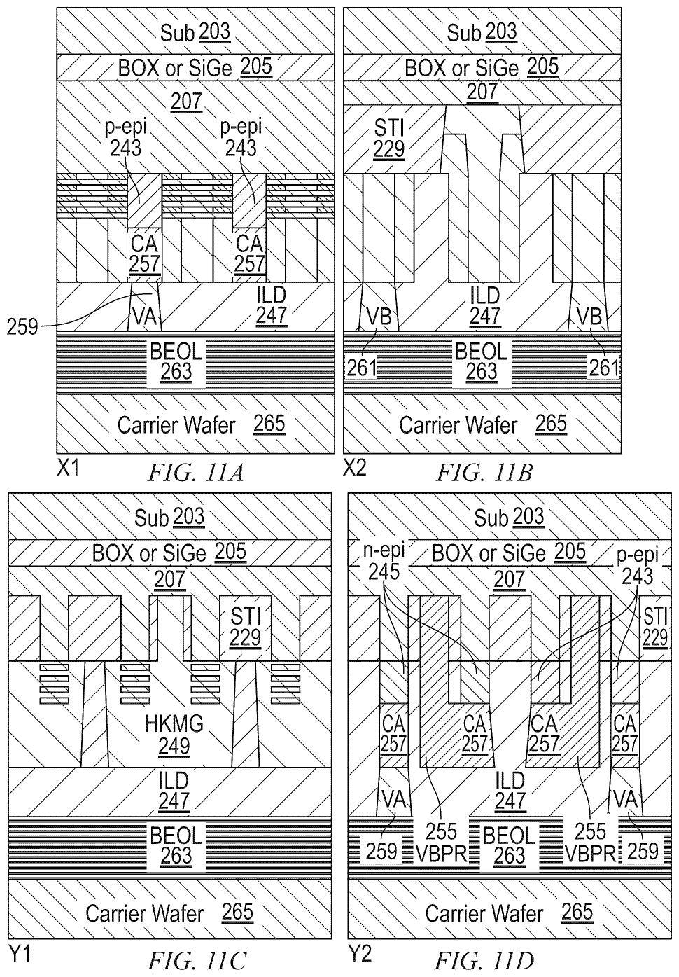

Refer now to FIGS. 11A, 111B, 11C, and 11D. FIG. 11A is a cross section of a structure taken along cutting plane line X1 in FIG. 5A, after inversion. FIG. 11B is a cross section of a structure taken along cutting plane line X2 in FIG. 5A, after inversion. FIG. 11C is a cross section of a structure taken along cutting plane line Y1 in FIG. 5A, after inversion. FIG. 11D is a cross section of a structure taken along cutting plane line Y2 in FIG. 5A, after inversion. FIGS. 11A-11D depict the structure of FIGS. 10A-10D after inversion or “flipping.” The skilled artisan is familiar with fixtures and techniques for flipping semiconductor wafers during fabrication.

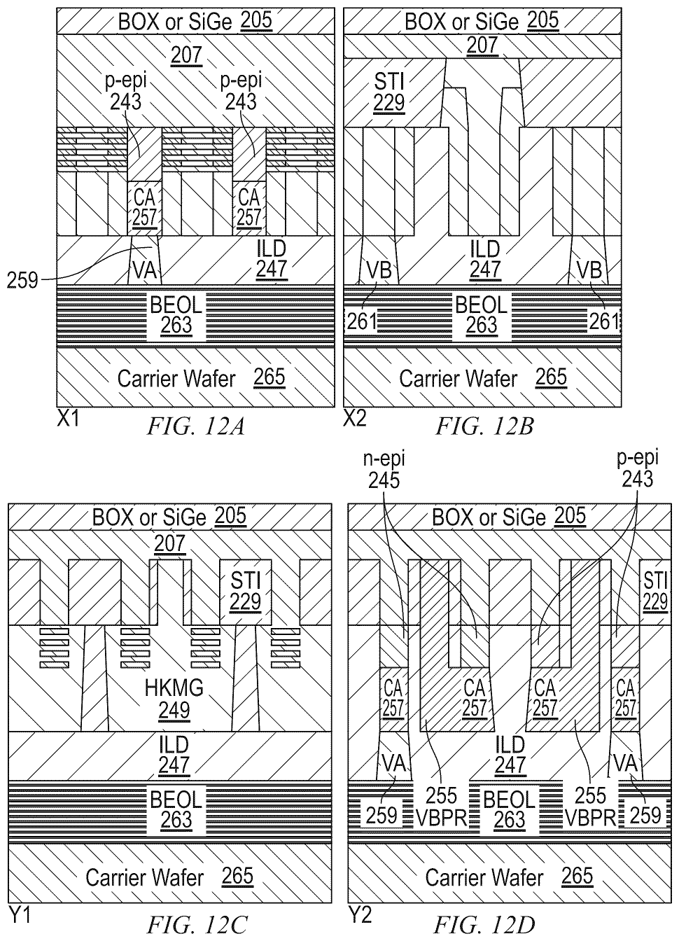

Refer now to FIGS. 12A, 12B, 12C, and 12D. FIG. 12A is a cross section of a structure taken along cutting plane line X1 in FIG. 5A, after the inversion. FIG. 12B is a cross section of a structure taken along cutting plane line X2 in FIG. 5A, after the inversion. FIG. 12C is a cross section of a structure taken along cutting plane line Y1 in FIG. 5A, after the inversion. FIG. 12D is a cross section of a structure taken along cutting plane line Y2 in FIG. 5A, after the inversion. FIGS. 12A-12D depict the structure of FIGS. 11A-11D after removal of the substrate 203, stopping on the etch stop layer 205. The skilled artisan is familiar with suitable etchants that will etch silicon and stop on oxide or SiGe.

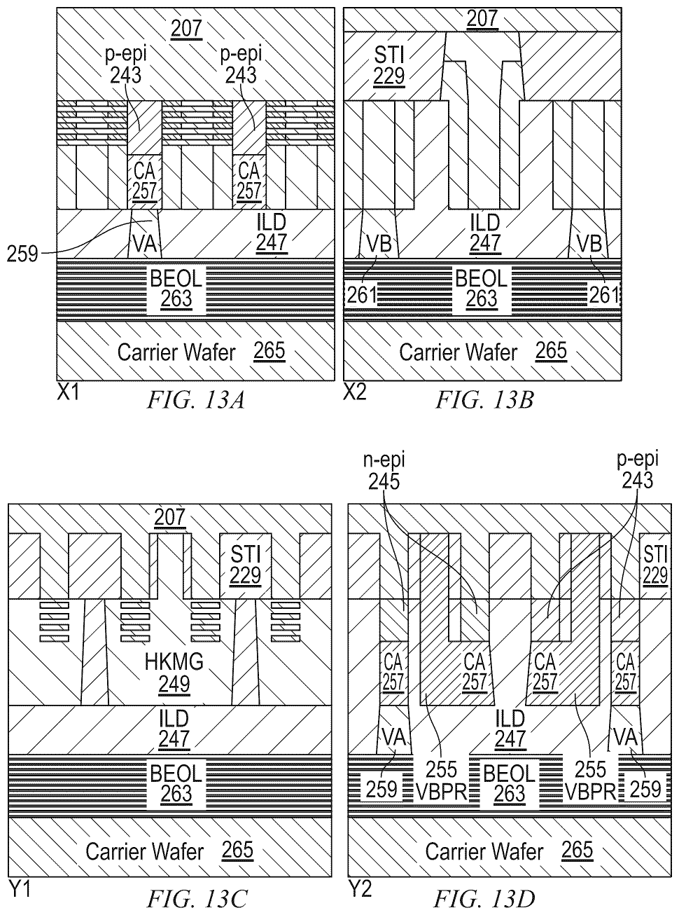

Refer now to FIGS. 13A, 13B, 13C, and 13D. FIG. 13A is a cross section of a structure taken along cutting plane line X1 in FIG. 5A, after the inversion. FIG. 13B is a cross section of a structure taken along cutting plane line X2 in FIG. 5A, after the inversion. FIG. 13C is a cross section of a structure taken along cutting plane line Y1 in FIG. 5A, after the inversion. FIG. 13D is a cross section of a structure taken along cutting plane line Y2 in FIG. 5A, after the inversion. FIGS. 13A-13D depict the structure of FIGS. 12A-12D after removal of the etch stop layer 205 (e.g., using a conventional wet etch process).

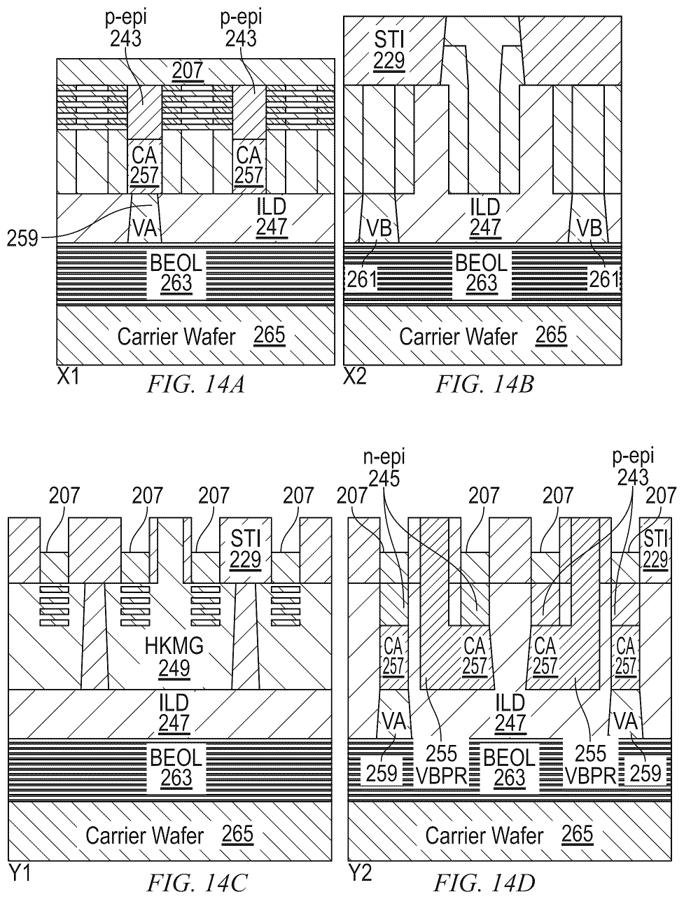

Refer now to FIGS. 14A, 14B, 14C, and 14D. FIG. 14A is a cross section of a structure taken along cutting plane line X1 in FIG. 5A, after the inversion. FIG. 14B is a cross section of a structure taken along cutting plane line X2 in FIG. 5A, after the inversion. FIG. 14C is a cross section of a structure taken along cutting plane line Y1 in FIG. 5A, after the inversion. FIG. 14D is a cross section of a structure taken along cutting plane line Y2 in FIG. 5A, after the inversion. FIGS. 14A-14D depict the structure of FIGS. 13A-13D after recessing the silicon substrate 207 (e.g., using a conventional dry etch process).

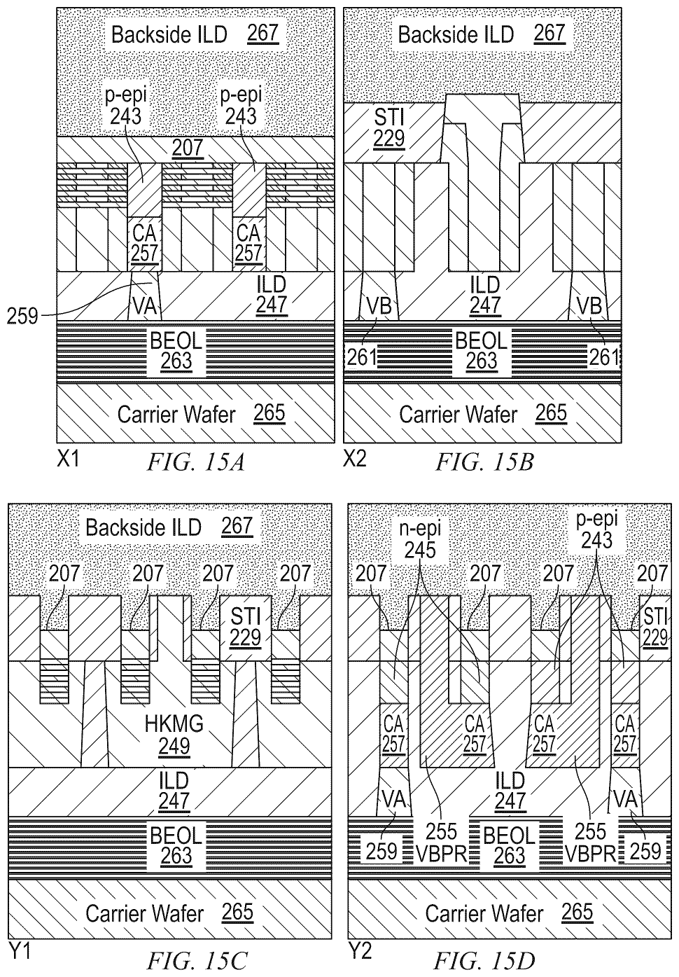

Refer now to FIGS. 15A, 15B, 15C, and 15D. FIG. 15A is a cross section of a structure taken along cutting plane line X1 in FIG. 5A, after the inversion. FIG. 15B is a cross section of a structure taken along cutting plane line X2 in FIG. 5A, after the inversion. FIG. 15C is a cross section of a structure taken along cutting plane line Y1 in FIG. 5A, after the inversion. FIG. 15D is a cross section of a structure taken along cutting plane line Y2 in FIG. 5A, after the inversion. FIGS. 15A-15D depict the structure of FIGS. 14A-14D after deposition of backside ILD 267 (materials and techniques suitable for ILD 247 can also be used for ILD 267).

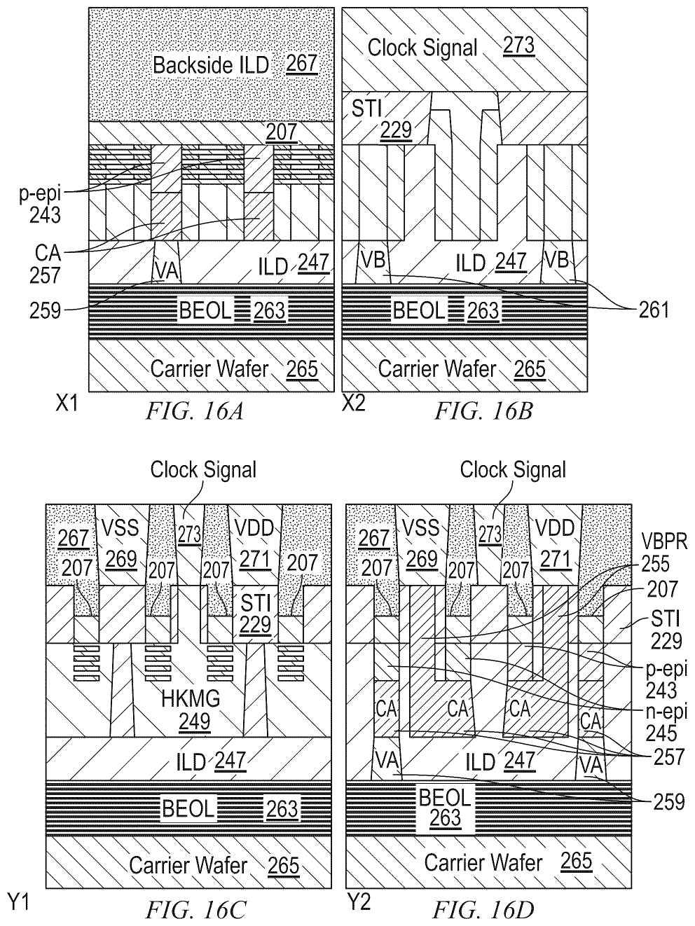

Refer now to FIGS. 16A, 16B, 16C, and 16D. FIG. 16A is a cross section of a structure taken along cutting plane line X1 in FIG. 5A, after the inversion. FIG. 16B is a cross section of a structure taken along cutting plane line X2 in FIG. 5A, after the inversion. FIG. 16C is a cross section of a structure taken along cutting plane line Y1 in FIG. 5A, after the inversion. FIG. 16D is a cross section of a structure taken along cutting plane line Y2 in FIG. 5A, after the inversion. FIGS. 16A-16D depict the structure of FIGS. 15A-15D after forming backside power rails (e.g., VSS 269, VDD 271) and signal lines (e.g., clock signal 273). The metallization process for various metal lines and vias can be done using conventional single damascene processes. Suitable materials include copper and other conductive metals. As discussed elsewhere herein, in one or more embodiments, the backside gate contact is self-aligned to the middle gate, and even if the gate is misaligned to the left or the right, the backside gate contact is connected to the bottom of the gate).

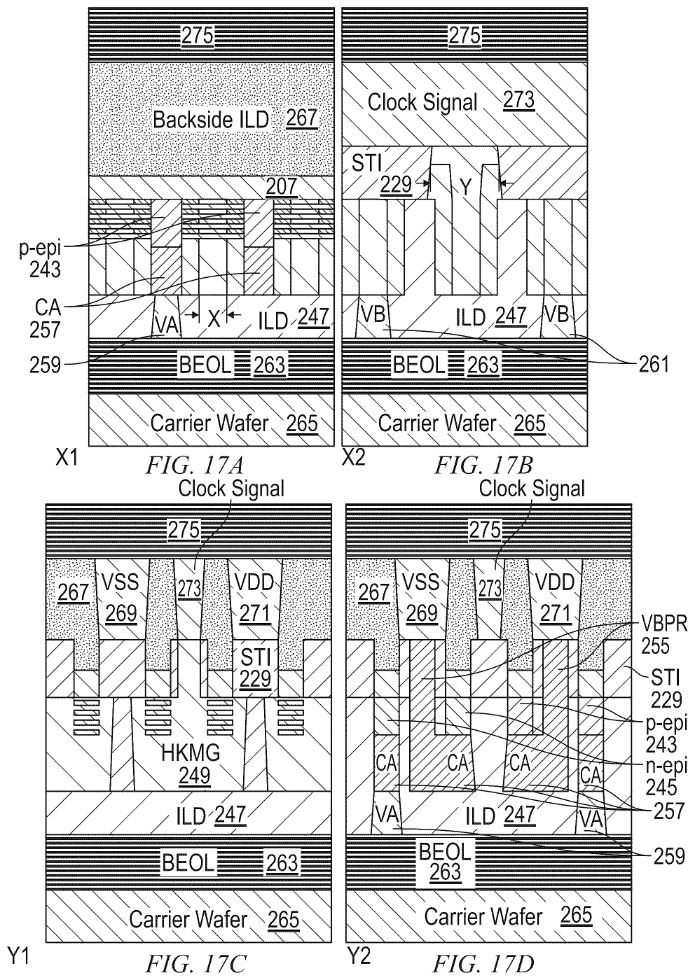

Refer now to FIGS. 17A, 17B, 17C, and 17D. FIG. 17A is a cross section of a structure taken along cutting plane line X1 in FIG. 5A, after the inversion. FIG. 17B is a cross section of a structure taken along cutting plane line X2 in FIG. 5A, after the inversion. FIG. 17C is a cross section of a structure taken along cutting plane line Y1 in FIG. 5A, after the inversion. FIG. 17D is a cross section of a structure taken along cutting plane line Y2 in FIG. 5A, after the inversion. FIGS. 17A-17D depict the structure of FIGS. 16A-16D after forming backside interconnects 275 (in general, the backside interconnect can contain a power distribution network, and can also contain wiring for signal routing). Given the teachings herein, the skilled artisan will be able to adapt conventional techniques to form the backside interconnects.

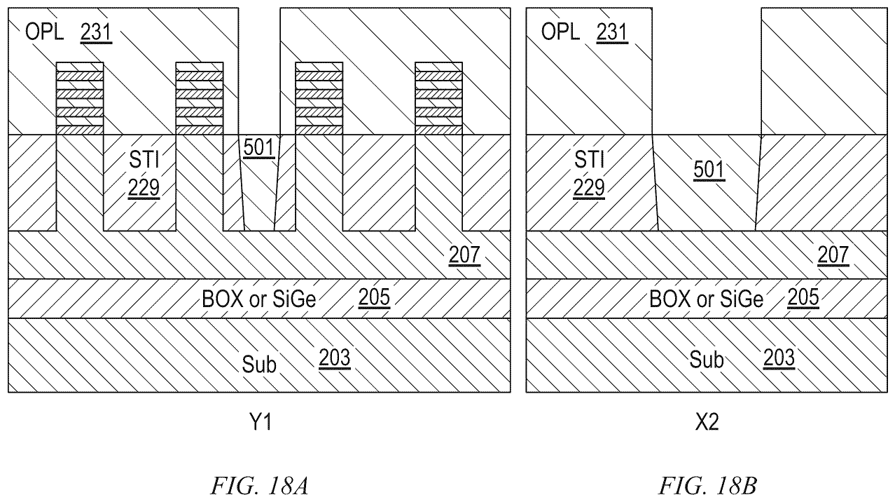

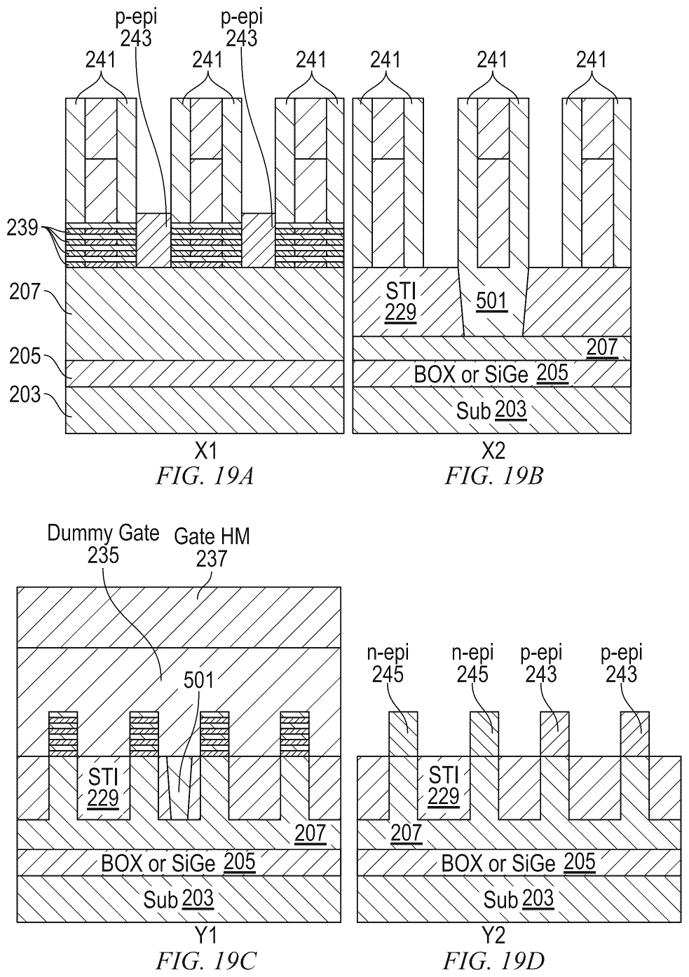

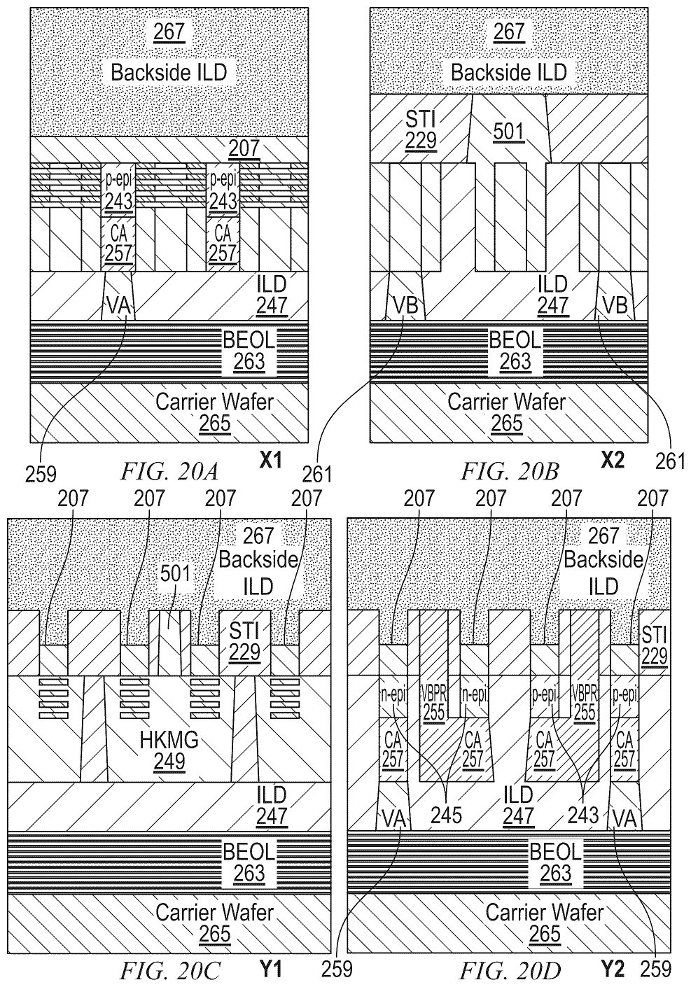

Consider now a second exemplary process flow, according to an aspect of the invention. The initial steps are identical to those discussed with regard to FIGS. 2A-5C. Refer now to FIGS. 18A and 18B. FIG. 18A is a cross section of a structure taken along cutting plane line Y1 in FIG. 5A. FIG. 18B is a cross section of a structure taken along cutting plane line X2 in FIG. 5A. FIGS. 18A and 18B depict the structure of FIGS. 5B and 5C after filling trenches 233 with sacrificial backside gate contact, such as silicon nitride (SiN) 501 and recessing same. Given the teachings herein, the skilled artisan can adapt known techniques for filling SiN or similar material and recessing same. In the second exemplary process flow, FIGS. 18A-19D are before inversion and FIGS. 20A-23D are after inversion.

Refer now to FIGS. 19A, 19B, 19C, and 19D. FIG. 19A is a cross section of a structure taken along cutting plane line X1 in FIG. 5A. FIG. 19B is a cross section of a structure taken along cutting plane line X2 in FIG. 5A. FIG. 19C is a cross section of a structure taken along cutting plane line Y1 in FIG. 5A. FIG. 19D is a cross section of a structure taken along cutting plane line Y2 in FIG. 5A. FIGS. 19A-19D depict the structure of FIGS. 18A and 18B after formation of a dummy gate 235, deposition of gate hard mask material 237, reactive ion etching (RIE) of the dummy gate material, spacers 241, recessing of the nanosheets, formation of inner spacers 239, and epitaxial growth of p-type source-drain regions 243 and n-type source-drain regions 245, in a manner analogous to FIGS. 6A-8D. Note that the dummy gate is shown as a unitary structure to avoid clutter, but can include, for example, a thin SiO₂ liner plus amorphous silicon (a-Si) in a known manner. For example, deposit the thin liner and then deposit amorphous Si material and carry out planarization; deposit gate hardmask material 237 (can be, e.g., a multilayer dielectric). The skilled artisan will have general familiarity with the dummy gate process. After lithographic patterning of the gate hard mask material 237, suitable etching, such as reactive ion etching (RIE), of the dummy gate material forms various gaps (not separately numbered) that will later contain inter-layer dielectric (ILD), epitaxially grown source-drain regions, and contacts, as will be apparent from the description that follows. For example, pattern the hardmask and etch the a-Si to form the dummy gates 235. The skilled artisan is familiar with techniques for lithographic patterning and etching. The skilled artisan is familiar with techniques for subsequent epitaxial growth of p-type and n-type source/drain regions and deposition of liners 241

The structure depicted in FIGS. 19A-19D can be subjected to processes analogous to those shown in FIGS. 9A-15D, including deposition of backside ILD 267, to obtain the structure shown in FIGS. 20A-20D. FIG. 20A is a cross section of a structure taken along cutting plane line X1 in FIG. 5A; FIG. 20B is a cross section of a structure taken along cutting plane line X2 in FIG. 5A; FIG. 20C is a cross section of a structure taken along cutting plane line Y1 in FIG. 5A; and FIG. 20D is a cross section of a structure taken along cutting plane line Y2 in FIG. 5A.

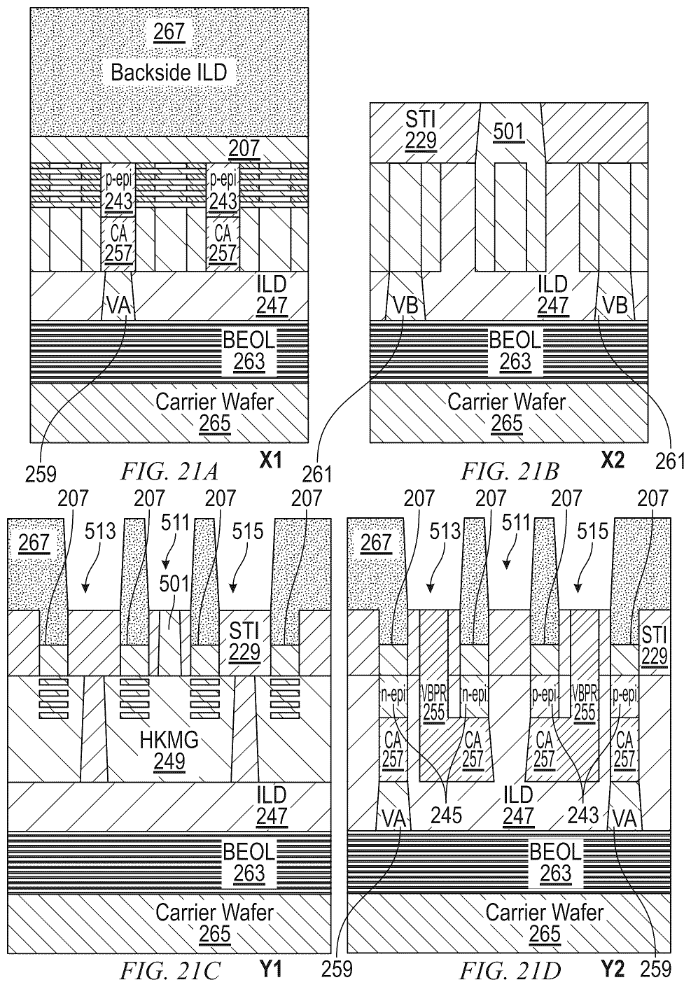

Conventional lithography and etching can be carried out for the backside BPR and signal lines, as part of the formation of the backside power rail and signal lines. Note cavities 511 for formation of clock signal lines; cavities 513 for formation of VSS power rails, and cavities 515 for formation of VDD power rails. FIG. 21A is a cross section of a structure taken along cutting plane line X1 in FIG. 5A; FIG. 21B is a cross section of a structure taken along cutting plane line X2 in FIG. 5A; FIG. 21C is a cross section of a structure taken along cutting plane line Y1 in FIG. 5A; and FIG. 21D is a cross section of a structure taken along cutting plane line Y2 in FIG. 5A. Known lithographic and etching techniques can be used for making the appropriate cavities in the backside ILD 267.

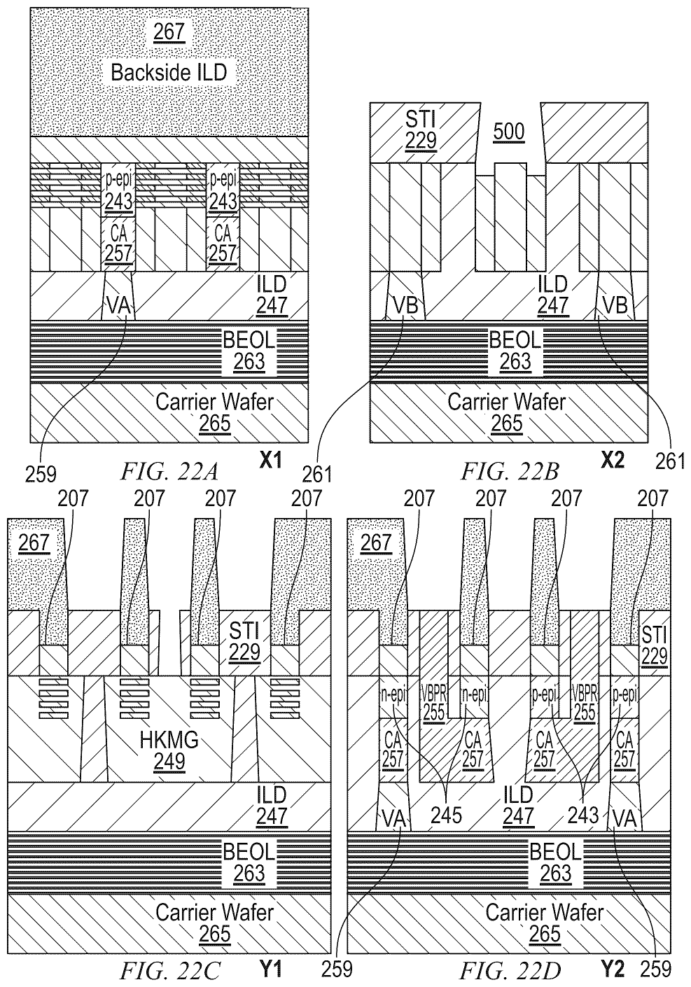

FIG. 22A is a cross section of a structure taken along cutting plane line X1 in FIG. 5A; FIG. 22B is a cross section of a structure taken along cutting plane line X2 in FIG. 5A; FIG. 22C is a cross section of a structure taken along cutting plane line Y1 in FIG. 5A; and FIG. 22D is a cross section of a structure taken along cutting plane line Y2 in FIG. 5A. FIGS. 22A-22D show the structure of FIGS. 21A-21D after selective removal of the sacrificial backside gate contact (e.g. SiN) 501 and removal of exposed HfO₂ from the HKMG 249 that are adjacent the SiN 501 (using, for example, conventional dry or wet etch processes).

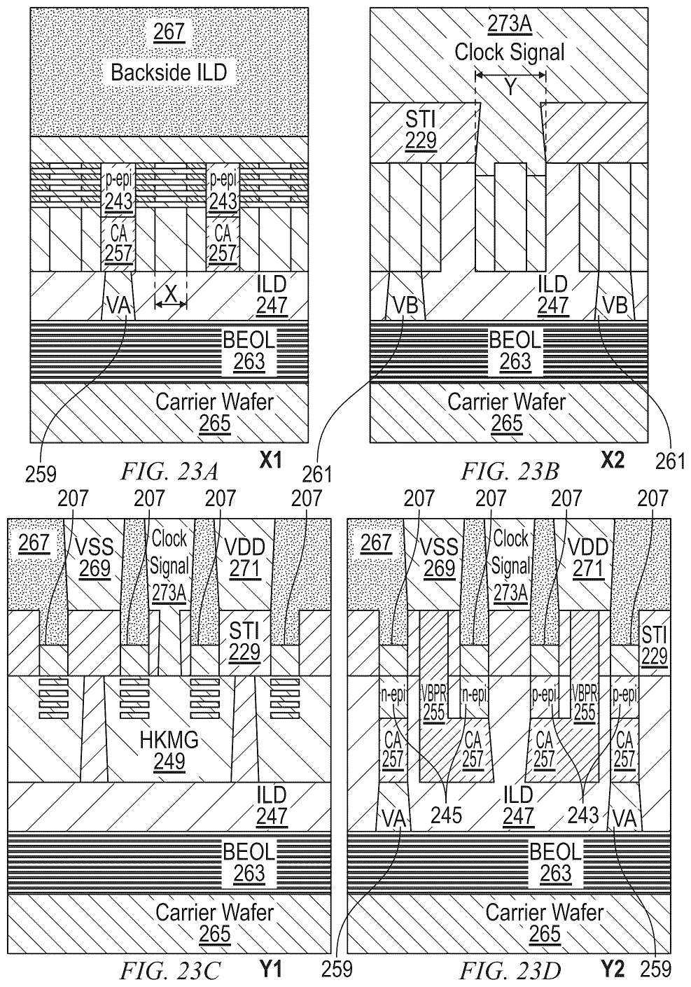

FIG. 23A is a cross section of a structure taken along cutting plane line X1 in FIG. 5A; FIG. 23B is a cross section of a structure taken along cutting plane line X2 in FIG. 5A; FIG. 23C is a cross section of a structure taken along cutting plane line Y1 in FIG. 5A; and FIG. 23D is a cross section of a structure taken along cutting plane line Y2 in FIG. 5A. FIGS. 23A-23D depict the structure of FIGS. 22A-22D after forming backside power rails (e.g., VSS 269, VDD 271) and signal lines (e.g., clock signal 273A). Clock signal lines 273A are similar to clock signal lines 273 but extend downward into the areas where the SiN 501 and exposed HfO₂ were removed. The metallization process for various metal lines and vias can be done using conventional single damascene processes. Suitable materials include copper and other conductive metals. As discussed elsewhere herein, in one or more embodiments, the backside gate contact is self-aligned to the middle gate, and even if the gate is misaligned to the left or the right, the backside gate contact is connected to the bottom of the gate).

Note that FIGS. 20A-23D show steps that could be performed analogously to move from the structures of FIGS. 15A-15D to those of FIGS. 16A-16D.

It is worth noting that various features will typically have a larger diameter towards the side of the structure from which they are formed, as seen, for example, in FIGS. 5B and 5C.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. As noted, the term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

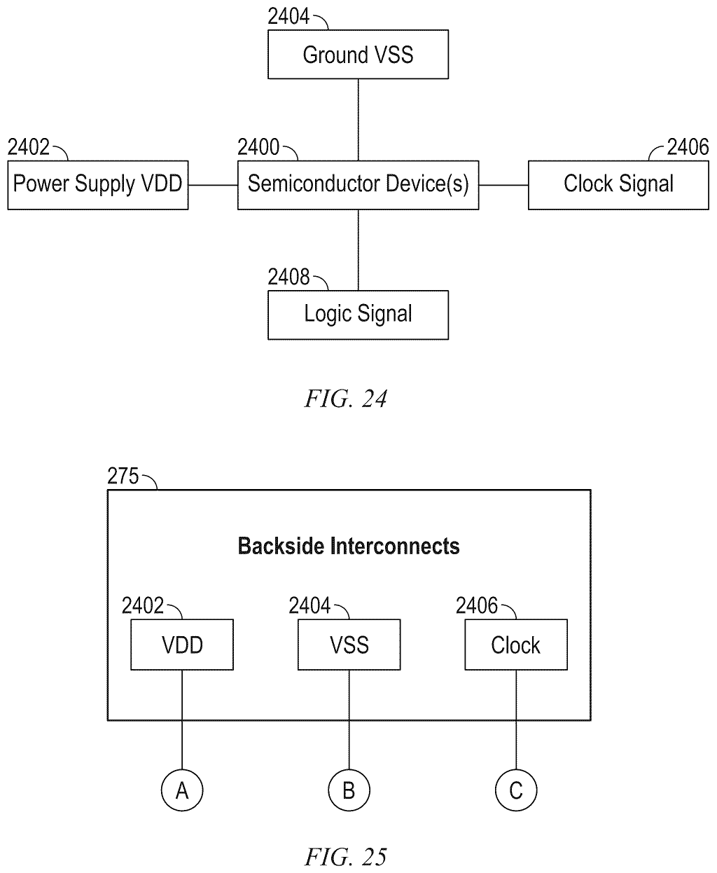

FIG. 25 shows a schematic of backside interconnects 275, in accordance with aspects of the inventions. The interconnects can include a voltage supply rail VDD 2404 coupled to the power supply 2402 of FIG. 24 and the VDD 271 (at “A”); a ground rail VSS 2404 coupled to the ground terminal 2404 of FIG. 24 and the VSS 269 (at “B”); and clock signal line 2406 coupled to the clock signal 2406 of FIG. 24 and the clock signal 273, 273A (at “C”). FIG. 25 is a schematic and the elements 2402, 2404, 2406 could be at different wiring levels.

Given the discussion thus far, it will be appreciated that, in general terms, an exemplary semiconductor structure includes a backside power rail (e.g., power portion 2402 of backside interconnects 275 with connections as discussed); a backside signal line (e.g., signal portion 2406 of backside interconnects 275 with connections as discussed); a first source-drain region (e.g., in FIG. 17A or 23A, the left-hand p-epi 243 or a corresponding n-epi in the case of an NFET); and a second source-drain region (e.g., in FIG. 17A or 23A, the right-hand p-epi 243 or a corresponding n-epi in the case of an NFET). Also included are at least one channel coupling the first and second source-drain regions (e.g., in FIG. 17A or 23A, the nanosheets between the first and second S/D regions); and a gate adjacent the at least one channel (e.g., in FIG. 17A or 23A, the gate surrounding the nanosheets, which connects to the clock signal 273, 273A in FIG. 17B or 23B). A frontside connection 257, 259 is provided to the first source-drain region (in one or more embodiments, the source/drain region wiring 257, 259 to the BEOL wiring 263 includes signal connections rather than power connections). A power connection (e.g., elements 257, 255, 271 in FIGS. 17D, 23D, or elements 257 255 269 in the case of an nFET) is provided from the backside power rail to the second source-drain region. A backside gate contact (e.g., element 273 plus the T-shaped portion of the gate in FIG. 17B, or element 273A in FIG. 23B) is provided from the gate to the backside signal line.

In some cases, the gate has a length and the backside gate contact has a bottom dimension larger than the gate length. See, e.g., discussions of dimensions X and Y below.

In some cases, as seen in FIG. 17B, the gate is a high-K metal gate, and the backside gate contact includes a T-shaped portion of the high-K metal gate.

In some cases, the backside signal line is a backside clock signal line. In some embodiments, the backside gate contact includes a portion of the backside clock signal line extending towards the gate (e.g., the metal coming down from element 273A in FIG. 23B).

In another aspect, an exemplary semiconductor array structure includes a substrate 207 and a plurality of field effect transistors located on the substrate. Each of the FETs includes a first source-drain region (e.g., in FIG. 17A or 23A, the left-hand p-epi 243 or a corresponding n-epi in the case of an NFET); and a second source-drain region (e.g., in FIG. 17A or 23A, the right-hand p-epi 243 or a corresponding n-epi in the case of an NFET). Also included in each FET is at least one channel coupling the first and second source-drain regions (e.g., in FIG. 17A or 23A, the nanosheets between the first and second S/D regions); and a gate that has a gate length X seen in FIGS. 17A and 23A and is adjacent the at least one channel (e.g., in FIG. 17A or 23A, the gate surrounding the nanosheets, which connects to the clock signal 273, 273A in FIG. 17B or 23B). As seen, for example, in the top view of FIG. 5A, the plurality of field effect transistors are arranged in rows.

The array structure further includes a plurality of frontside signal lines on a front side of the plurality of field effect transistors (e.g., portion of BEOL wiring 263 that connects to VA (via connecting source-drain contact to BEOL wiring) 259 in FIGS. 17A and, 23A). In one or more embodiments, the source/drain region wiring 257, 259 to the BEOL wiring 263 includes signal connections rather than power connections, because the power supply is moved to the backside/FEOL. Thus, also included are a plurality of backside power rails on a back side of the plurality of field effect transistors (e.g., a power portion of backside interconnects 275 as per FIG. 25 coupled to VSS 269 to the n-epi and VDD 271 to the p-epi in FIGS. 17D and 23D). A plurality of backside signal wires (e.g., signal portion of backside interconnects 275 that connect to elements 273, 273A in FIGS. 17B and 23B) are provided on the back side of the plurality of field effect transistors. A plurality of frontside signal connections 257, 259 are provided from the plurality of frontside signal lines to the first source-drain regions. A plurality of power connections (elements 257, 255, 271 in FIGS. 17D and 23D, or elements 257 255 269 for an nFET) are provided from the backside power rails to the second source-drain regions. A plurality of backside gate contact connections (e.g., element 273 plus the T-shaped portion of the gate in FIG. 17B, or element 273A in FIG. 23B) are provided from the backside signal wires to the gates; the backside gate contact connections each have a bottom dimension Y seen in FIGS. 17B and 23B that is larger than the gate length X.

In some instances, the gates of the plurality of field effect transistors comprise high-K metal gates and the plurality of backside gate contact connections include T-shaped portions of the high-K metal gates, as seen in FIG. 17B. In some cases, the backside signal wires comprise backside clock signal wires. In some cases, the plurality of backside gate contact connections include portions of the backside clock signal wires extending towards the gates (e.g., the metal coming down from element 273A in FIG. 23B).

Referring, for example, to FIG. 5A, in one or more embodiments, first adjacent pairs of the rows of transistors are n-type 109 and second adjacent pairs of said rows of transistors are p-type 111. In some cases, the backside clock signal wires 273 (also true for 273A) are located between corresponding ones of the n-type rows and the p-type rows. In some instances, the backside power connections and backside power rails are located between pairs of the n-type rows (e.g., VSS 269) and between pairs of the p-type rows (e.g., VDD 271).

In one or more embodiments, the channels comprise nanosheet channel regions (e.g., in FIG. 17A or 23A, the nanosheets between the first and second S/D regions) and the gates comprise all-around gates (e.g., in FIG. 17A or 23A, the gate surrounding the nanosheets, which connects to the clock signal 273, 273A in FIG. 17B or 23B).

Referring to FIG. 24, in one or more embodiments, the array structure further includes a first signal source (e.g., clock signal 2406) coupled to the plurality of backside signal wires; a logic signal source 2408 coupled to the plurality of frontside signal lines; and a power supply coupled to the plurality of backside power rails (e.g., power supply 2402 coupled to VDD and ground terminal 2404 coupled to VSS). Element 2400 generally represents an individual device or an array of devices, according to any of the disclosed embodiments.

In another aspect, referring to FIGS. 2A-17D, an exemplary method of forming a semiconductor structure includes, as seen in FIG. 3, defining n-type and p-type active regions in a nanosheet stack on a substrate 203, and, as seen in FIG. 4, forming shallow trench isolation (STI) regions 229 between the active regions (as illustrated, in one or more embodiments, while located between the active regions, the STI does not extend to the top of the nanosheet stacks). It should be noted that the active regions are referred to as n-type and p-type for convenience, it being understood that in one or more embodiments, n-type and p-type source/drain regions are epitaxially grown at a later time. Referring to FIGS. 5A-5C, one or more embodiments further include forming backside gate contact vias 233 in the shallow trench isolation (STI) regions 229 in spaces between the n-type and p-type active regions.

Referring to FIGS. 6A-7D, the exemplary method further includes forming dummy gates 235, and, referring to FIGS. 8A-8D, also includes forming gate spacers 241. As best seen in FIGS. 7B and 8B, bottom portions 236 (note the “T” shape in the example) of the backside gate contact vias are filled with dummy gate material of the dummy gates 235. As noted elsewhere, FIGS. 8A-8D depict the structure of FIGS. 7A-7D after formation of gate spacer 241, recessing of the nanosheets, formation of inner spacers 239, and epitaxial growth of p-type source-drain regions 243 and n-type source-drain regions 245. As best seen in FIG. 8B, the spacers 241 are on the thinner vertical part of the “T” and extend laterally to a thickness equal to the projecting crossbar of the “T.” In the end structure, the region 236 will be filled with HKMG material as discussed below and the resulting region 253 will be isolated from the FEOL structures by the gate spacers 241.

Referring to FIGS. 9A-9D, the method further includes removing the dummy gates and forming replacement high-K metal gates 249 such that the backside gate contact vias are filled with high-K metal gate material 253 of the high-K metal gates adjacent bottoms of the gates (at 253 high-K metal gate material replaces dummy material at 236). As discussed elsewhere, to move from the structure of FIGS. 8A-8D to the structure of FIGS. 9A-9D, selectively remove the sacrificial a-Si portion of the dummy gate 235 and sacrificial nanosheets 209, 211, 213, 215; form conformal High-K metal gate stacks; pattern and etch cavities for the gate cuts 251; and fill the cavities with dielectric material to form the gate cuts 251. FIGS. 9A-9D thus depict the resultant structure of these operations.

Referring to FIGS. 10A-10D, the method further includes, on a frontside of the resultant structure, opposite the substrate, forming back end of line wiring 263. In particular, FIGS. 10A-10D depict the structure of FIGS. 9A-9D after forming middle of line (MOL) contacts, back end of line (BEOL) interconnect(s), and carrier wafer bonding. Note the VBPR (via for connection to backside power rail) 255, source/drain contact (CA) 257, VA (via connecting source-drain contact to BEOL wiring) 259, VB (via connecting gate to BEOL wiring) 261, BEOL wiring 263, and carrier wafer 265.

Referring to FIGS. 11A-17D, the method further includes forming backside (substrate side) signal lines (e.g., clock signal 273) connecting to the HKMG material 253 in the backside gate contact vias.

In some cases, referring to FIGS. 8A-8D, the method further includes growing p-type 243 and n-type 245 source drain regions in the p-type and n-type active regions, with nanosheets of the nanosheet stack forming channels therebetween. This defines a plurality of p-type field effect transistors each including first and second corresponding ones of the p-type source drain regions and a plurality of n-type field effect transistors each including first and second corresponding ones of the n-type source drain regions. A further step as seen in FIGS. 16A-16D includes forming backside power rails connecting to the second corresponding ones of the p-type source drain regions and the second corresponding ones of the n-type source drain regions. Note the respective backside power elements (VSS 269, VDD 271) connected to the S/D epitaxy

In some cases, referring to FIGS. 10A-10D, a further method step includes forming frontside signal elements (e.g., VA 259) connecting to the first corresponding ones of the p-type source drain regions and the first corresponding ones of the n-type source drain regions.

In yet another aspect, referring again to FIGS. 3-5C, and also to FIGS. 18A-23D, another exemplary method of forming a semiconductor structure includes, as seen in FIG. 3, defining n-type and p-type active regions in a nanosheet stack on a substrate 203, and, as seen in FIG. 4, forming shallow trench isolation (STI) regions 229 between the active regions (as illustrated, in one or more embodiments, while located between the active regions, the STI does not extend to the top of the nanosheet stacks). It should be noted that the active regions are referred to as n-type and p-type for convenience, it being understood that in one or more embodiments, n-type and p-type source/drain regions are epitaxially grown at a later time. Referring to FIGS. 5A-5C, one or more embodiments further include forming backside gate contact vias 233 in the shallow trench isolation (STI) regions 229 in spaces between the n-type and p-type active regions.

Referring to FIGS. 18A and 18B, the method further includes filling the backside gate contact vias with sacrificial backside gate contact material (e.g., silicon nitride (SiN) 501) and recessing the sacrificial backside gate contact material. For example, the sacrificial backside gate contact material can be recessed to a level even with the bottoms of the nanosheets.

Referring to FIGS. 19A-19D, the method further includes forming dummy gates 235 and gate spacers 241, such that bottom portions of the backside gate contact vias are filled with the sacrificial backside gate contact material 501 in contact with the dummy gate material of the dummy gates 235. In the example of FIGS. 19A-19D, the spacers 241 also have bottom portions adjacent to the sacrificial backside gate contact material 501.

Referring to FIGS. 20A-20D, the method still further includes removing the dummy gates and forming replacement high-K metal gates 249 such that the bottom portions of the backside gate contact vias are filled with the sacrificial backside gate contact material 501 in contact with high-K metal gate material of the high-K metal gates 249. A resultant intermediate structure analogous to that depicted in FIGS. 9A-9D is obtained.

Referring again to FIGS. 20A-20D, the method further includes, on a frontside of the resultant structure, opposite the substrate, forming back end of line wiring 263. In particular, FIGS. 20A-20D depict the structure of FIGS. 19A-19D after forming middle of line (MOL) contacts, back end of line (BEOL) interconnect(s), and carrier wafer bonding. Note the VBPR (via for connection to backside power rail) 255, source/drain contact (CA) 257, VA (via connecting source-drain contact to BEOL wiring) 259, VB (via connecting gate to BEOL wiring) 261, BEOL wiring 263, and carrier wafer 265.

As best seen in FIG. 22B, the method further includes removing the sacrificial backside gate contact material 501. In the example, an adjacent part of the gate spacers 241 is also removed. The resulting void is denoted as 500.

Referring to FIGS. 21A-23D, the method further includes forming backside (substrate side) signal lines (e.g., clock signal 273A) that connect to the HKMG material 249 in the backside gate contact vias through the region 500 where the sacrificial backside gate contact material 501 was removed, as best seen in FIG. 23B.

In some cases, referring to FIGS. 19A-19D, the method further includes growing p-type 243 and n-type 245 source drain regions in the p-type and n-type active regions, with nanosheets of the nanosheet stack forming channels therebetween. This defines a plurality of p-type field effect transistors each including first and second corresponding ones of the p-type source drain regions and a plurality of n-type field effect transistors each including first and second corresponding ones of the n-type source drain regions. A further step as seen in FIGS. 23A-23D includes forming backside power rails connecting to the second corresponding ones of the p-type source drain regions and the second corresponding ones of the n-type source drain regions. Note the respective backside power rails (VSS 269, VDD 271) connected to the S/D epitaxy.

In some cases, referring to FIGS. 20A-20D, a further method step includes forming frontside signal connections (e.g., VA 259) connecting to the first corresponding ones of the p-type source drain regions and the first corresponding ones of the n-type source drain regions.

One or more embodiments are implemented in the context of gate all-round nanosheet technology, as shown in the non-limiting exemplary embodiments. Thus, in one or more embodiments, the NFETs and PFETs include channel regions in the form of nanosheet channel regions; and the NFETs and PFETs include gates in the form of all-around gates. However, the skilled artisan will appreciate that techniques disclosed herein can also be employed with other types of transistors, for example.

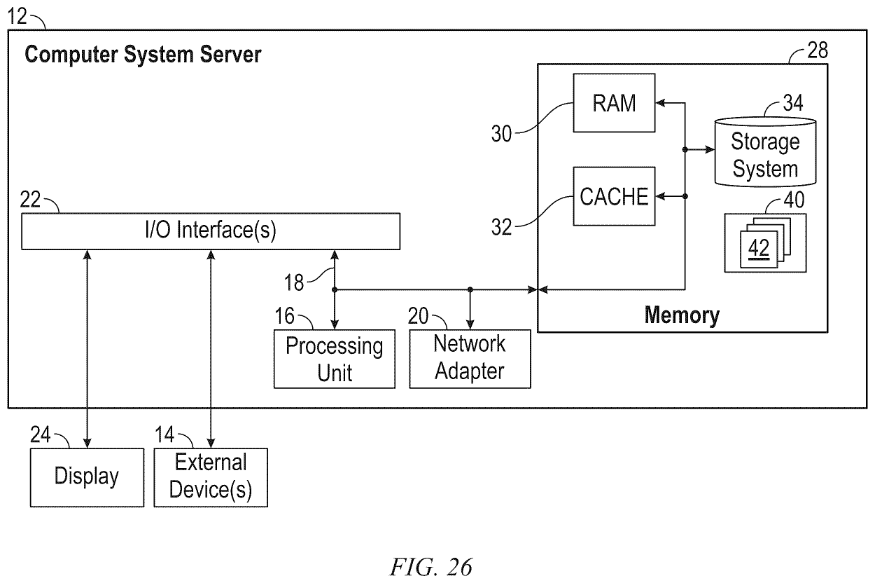

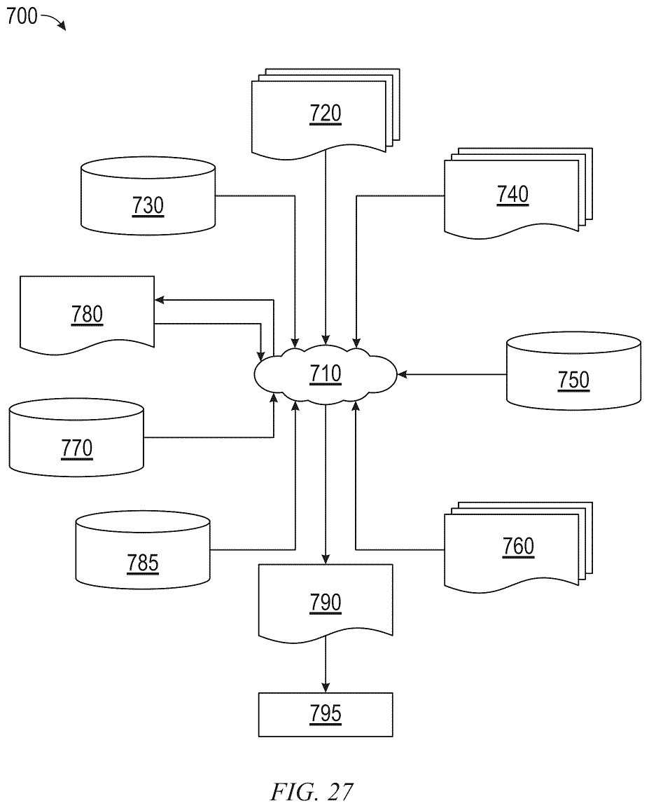

FIG. 26 depicts a computer system 12 that can be used, for example, to carry out a design process as described below with respect to FIG. 27. Computer system 12 includes, for example, one or more processors or processing units 16, a system memory 28, and a bus 18 that couples various system components including system memory 28 to processor 16. Element 16 can connect to the bus, for example, with suitable bus interface units.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus.

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random-access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below memory 28 may include at least one program product having a set (e.g., at least one) of program modules that are configured to carry out, e.g., a design process as shown in FIG. 27.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out software-implemented functions and/or methodologies.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, and external disk drive arrays, RAID systems, tape drives, and data archival storage systems, etc.

Still with reference to FIG. 26, note processor 16, memory 28, and an input/output interface 22 to a display 24 and external device(s) 14 such as a keyboard, a pointing device, or the like. The term “processor” as used herein is intended to include any processing device, such as, for example, one that includes a CPU (central processing unit) and/or other forms of processing circuitry. Further, the term “processor” may refer to more than one individual processor. The term “memory” is intended to include memory associated with a processor or CPU, such as, for example, RAM (random access memory) 30, ROM (read only memory), a fixed memory device (for example, hard drive 34), a removable memory device (for example, diskette), a flash memory and the like. In addition, the phrase “input/output interface” as used herein, is intended to contemplate an interface to, for example, one or more mechanisms for inputting data to the processing unit (for example, mouse), and one or more mechanisms for providing results associated with the processing unit (for example, printer). The processor 16, memory 28, and input/output interface 22 can be interconnected, for example, via bus 18 as part of a data processing unit 12. Suitable interconnections, for example via bus 18, can also be provided to a network interface 20, such as a network card, which can be provided to interface with a computer network, and to a media interface, such as a diskette or CD-ROM drive, which can be provided to interface with suitable media.

Accordingly, computer software including instructions or code for performing desired tasks, may be stored in one or more of the associated memory devices (for example, ROM, fixed or removable memory) and, when ready to be utilized, loaded in part or in whole (for example, into RAM) and implemented by a CPU. Such software could include, but is not limited to, firmware, resident software, microcode, and the like.

A data processing system suitable for storing and/or executing program code will include at least one processor 16 coupled directly or indirectly to memory elements 28 through a system bus 18. The memory elements can include local memory employed during actual implementation of the program code, bulk storage, and cache memories 32 which provide temporary storage of at least some program code in order to reduce the number of times code must be retrieved from bulk storage during implementation.

Input/output or I/O devices (including but not limited to keyboards, displays, pointing devices, and the like) can be coupled to the system either directly or through intervening I/O controllers.

Network adapters 20 may also be coupled to the system to enable the data processing system to become coupled to other data processing systems or remote printers or storage devices through intervening private or public networks. Modems, cable modem and Ethernet cards are just a few of the currently available types of network adapters.

As used herein, including the claims, a “server” includes a physical data processing system (for example, system 12 as shown in FIG. 26) running a server program. It will be understood that such a physical server may or may not include a display and keyboard. Furthermore, FIG. 26 is representative of a conventional general-purpose computer that could be used, for example, to implement aspects of the design process described below.

### Exemplary Design Process Used in Semiconductor Design, Manufacture, and/or Test

One or more embodiments of hardware in accordance with aspects of the invention can be implemented using techniques for semiconductor integrated circuit design simulation, test, layout, and/or manufacture. In this regard, FIG. 27 shows a block diagram of an exemplary design flow 700 used for example, in semiconductor IC logic design, simulation, test, layout, and manufacture. Design flow 700 includes processes, machines and/or mechanisms for processing design structures or devices to generate logically or otherwise functionally equivalent representations of design structures and/or devices, such as those disclosed herein or the like. The design structures processed and/or generated by design flow 700 may be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g., e-beam writers), computers or equipment for simulating design structures, any apparatus used in the manufacturing or test process, or any machines for programming functionally equivalent representations of the design structures into any medium (e.g., a machine for programming a programmable gate array).

Design flow 700 may vary depending on the type of representation being designed. For example, a design flow 700 for building an application specific IC (ASIC) may differ from a design flow 700 for designing a standard component or from a design flow 700 for instantiating the design into a programmable array, for example a programmable gate array (PGA) or a field programmable gate array (FPGA) offered by Altera® Inc. or Xilinx® Inc.

FIG. 27 illustrates multiple such design structures including an input design structure 720 that is preferably processed by a design process 710. Design structure 720 may be a logical simulation design structure generated and processed by design process 710 to produce a logically equivalent functional representation of a hardware device. Design structure 720 may also or alternatively comprise data and/or program instructions that when processed by design process 710, generate a functional representation of the physical structure of a hardware device. Whether representing functional and/or structural design features, design structure 720 may be generated using electronic computer-aided design (ECAD) such as implemented by a core developer/designer. When encoded on a gate array or storage medium or the like, design structure 720 may be accessed and processed by one or more hardware and/or software modules within design process 710 to simulate or otherwise functionally represent an electronic component, circuit, electronic or logic module, apparatus, device, or system. As such, design structure 720 may comprise files or other data structures including human and/or machine-readable source code, compiled structures, and computer executable code structures that when processed by a design or simulation data processing system, functionally simulate or otherwise represent circuits or other levels of hardware logic design. Such data structures may include hardware-description language (HDL) design entities or other data structures conforming to and/or compatible with lower-level HDL design languages such as Verilog and VHDL, and/or higher-level design languages such as C or C++.

Design process 710 preferably employs and incorporates hardware and/or software modules for synthesizing, translating, or otherwise processing a design/simulation functional equivalent of components, circuits, devices, or logic structures to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describes the connections to other elements and circuits in an integrated circuit design. Netlist 780 may be synthesized using an iterative process in which netlist 780 is resynthesized one or more times depending on design specifications and parameters for the device. As with other design structure types described herein, netlist 780 may be recorded on a machine-readable data storage medium or programmed into a programmable gate array. The medium may be a nonvolatile storage medium such as a magnetic or optical disk drive, a programmable gate array, a compact flash, or other flash memory. Additionally, or in the alternative, the medium may be a system or cache memory, buffer space, or other suitable memory.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 770, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710 without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures along with any additional mechanical design or data (if applicable), to generate a second design structure 790. Design structure 790 resides on a storage medium or programmable gate array in a data format used for the exchange of data of mechanical devices and structures (e.g., information stored in an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on data storage media and that when processed by an ECAD system generate a logically or otherwise functionally equivalent form of one or more IC designs or the like as disclosed herein. In one embodiment, design structure 790 may comprise a compiled, executable HDL simulation model that functionally simulates the devices disclosed herein.

Design structure 790 may also employ a data format used for the exchange of layout data of integrated circuits and/or symbolic data format (e.g., information stored in a GDSII (GDS2), GL1, OASIS, map files, or any other suitable format for storing such design data structures). Design structure 790 may comprise information such as, for example, symbolic data, map files, test data files, design content files, manufacturing data, layout parameters, wires, levels of metal, vias, shapes, data for routing through the manufacturing line, and any other data required by a manufacturer or other designer/developer to produce a device or structure as described herein. Design structure 790 may then proceed to a stage 795 where, for example, design structure 790: proceeds to tape-out, is released to manufacturing, is released to a mask house, is sent to another design house, is sent back to the customer, etc.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A semiconductor structure comprising:
a backside power rail;
a backside signal line;
a frontside signal line;
a first source-drain region;
a second source-drain region;
at least one channel coupling the first and second source-drain regions;
a gate adjacent the at least one channel;
a frontside signal connection from the frontside signal line to the first source-drain region;
a power connection from the backside power rail to the second source-drain region; and
a backside gate contact from the gate to the backside signal line.

2. The semiconductor device of claim 1, wherein the gate has a length and wherein the backside gate contact has a bottom dimension larger than the gate length.

3. The semiconductor device of claim 2, wherein the gate comprises a high-K metal gate and wherein the backside gate contact includes a T-shaped portion of the high-K metal gate.

4. The semiconductor device of claim 2, wherein the backside signal line comprises a backside clock signal line, and wherein the backside gate contact includes a portion of the backside clock signal line extending towards the gate.

5. A semiconductor array structure comprising:
a substrate;
a plurality of field effect transistors located on the substrate, each comprising a first source-drain region, a second source-drain region, at least one channel coupling the first and second source-drain regions, and a gate, having a gate length, and being adjacent to the at least one channel, the plurality of field effect transistors being arranged in rows;
a plurality of frontside signal lines on a front side of the plurality of field effect transistors;
a plurality of backside power rails on a back side of the plurality of field effect transistors;
a plurality of backside signal wires on the back side of the plurality of field effect transistors;
a plurality of frontside signal connections from the plurality of frontside signal lines to the first source-drain regions;
a plurality of power connections from the backside power rails to the second source-drain regions; and
a plurality of backside gate contact connections from the backside signal wires to the gates, the backside gate contact connections each having a bottom dimension larger than the gate length.

6. The semiconductor array structure of claim 5, wherein the gates of the plurality of field effect transistors comprise high-K metal gates and wherein the plurality of backside gate contact connections include T-shaped portions of the high-K metal gates.

7. The semiconductor array structure of claim 5, wherein the backside signal wires comprise backside clock signal wires, and wherein the plurality of backside gate contact connections include portions of the backside clock signal wires extending towards the gates.

8. The semiconductor array structure of claim 7, wherein first adjacent pairs of said rows are n-type and second adjacent pairs of said rows are p-type.

9. The semiconductor array structure of claim 8, wherein the backside clock signal wires are located between corresponding ones of the n-type rows and the p-type rows.

10. The semiconductor array structure of claim 9, wherein the backside power connections and backside power rails are located between pairs of the n-type rows and between pairs of the p-type rows.

11. The semiconductor array structure of claim 5, wherein:
the channels comprise nanosheet channel regions; and
the gates comprise all-around gates.

12. The semiconductor array structure of claim 5, further comprising:
a first signal source coupled to the plurality of backside signal wires;
a second signal source coupled to the plurality of frontside signal lines; and
a power supply coupled to the plurality of backside power rails.

13. A method of forming a semiconductor structure, comprising:
defining n-type and p-type active regions in a nanosheet stack on a substrate and forming shallow trench isolation (STI) regions between the active regions;
forming backside gate contact vias in the shallow trench isolation (STI) regions in spaces between the n-type and p-type active regions;
forming dummy gates and gate spacers, such that bottom portions of the backside gate contact vias are filled with dummy gate material of the dummy gates;
removing the dummy gates and forming replacement high-K metal gates such that the backside gate contact vias are filled with high-K metal gate material of the high-K metal gates adjacent bottoms of the gates, to obtain a resultant structure;
on a frontside of the resultant structure opposite the substrate, forming back end of line wiring; and
forming backside signal lines connecting to the high-K metal gate material in the backside gate contact vias.

14. The method of claim 13, further comprising:
growing p-type and n-type source drain regions in the p-type and n-type active regions, with nanosheets of the nanosheet stack forming channels therebetween, to define a plurality of p-type field effect transistors each including first and second corresponding ones of the p-type source drain regions and a plurality of n-type field effect transistors each including first and second corresponding ones of the n-type source drain regions; and
forming backside power rails connecting to the second corresponding ones of the p-type source drain regions and the second corresponding ones of the n-type source drain regions.

15. The method of claim 14, further comprising forming frontside signal connections connecting to the first corresponding ones of the p-type source drain regions and the first corresponding ones of the n-type source drain regions.

16. A method of forming a semiconductor structure, comprising:
defining n-type and p-type active regions in a nanosheet stack on a substrate and forming shallow trench isolation (STI) regions between the active regions;
forming backside gate contact vias in the shallow trench isolation (STI) regions in spaces between the n-type and p-type active regions;
filling the backside gate contact vias with sacrificial backside gate contact material and recessing the sacrificial backside gate contact material;
forming dummy gates and gate spacers, such that bottom portions of the backside gate contact vias are filled with the sacrificial backside gate contact material in contact with dummy gate material of the dummy gates;
removing the dummy gates and forming replacement high-K metal gates such that the bottom portions of the backside gate contact vias are filled with the sacrificial backside gate contact material in contact with high-K metal gate material of the high-K metal gates, to obtain a resultant structure;
on a frontside of the resultant structure opposite the substrate, forming back end of line wiring;
removing the sacrificial backside gate contact material to form voids; and
forming backside signal lines connecting to the high-K metal gate material through the voids.

17. The method of claim 16, further comprising:
growing p-type and n-type source drain regions in the p-type and n-type active regions, with nanosheets of the nanosheet stack forming channels therebetween, to define a plurality of p-type field effect transistors each including first and second corresponding ones of the p-type source drain regions and a plurality of n-type field effect transistors each including first and second corresponding ones of the n-type source drain regions; and
forming backside power rails connecting to the second corresponding ones of the p-type source drain regions and the second corresponding ones of the n-type source drain regions.

18. The method of claim 17, further comprising forming frontside signal connections connecting to the first corresponding ones of the p-type source drain regions and the first corresponding ones of the n-type source drain regions.

19. A hardware description language (HDL) design structure encoded on a machine-readable data storage medium, the HDL design structure comprising elements that when processed in a computer-aided design system generates a machine-executable representation of a semiconductor array structure, wherein the HDL design structure comprises:
a substrate;
a plurality of field effect transistors located on the substrate, each comprising a first source-drain region, a second source-drain region, at least one channel coupling the first and second source-drain regions, and a gate having a gate length adjacent the at least one channel, the plurality of field effect transistors being arranged in rows;
a plurality of frontside signal lines on a front side of the plurality of field effect transistors;
a plurality of backside power rails on a back side of the plurality of field effect transistors;
a plurality of backside signal wires on the back side of the plurality of field effect transistors;
a plurality of frontside signal connections from the plurality of frontside signal lines to the first source-drain regions;
a plurality of power connections from the backside power rails to the second source-drain regions; and
a plurality of backside gate contact connections from the backside signal wires to the gates, the backside gate contact connections each having a bottom dimension larger than the gate length.

20. The design structure of claim 19, wherein the gates of the plurality of field effect transistors comprise high-K metal gates and wherein the plurality of backside gate contact connections include T-shaped portions of the high-K metal gates.

21. The design structure of claim 19, wherein the backside signal wires comprise backside clock signal wires, wherein the plurality of backside gate contact connections include portions of the backside clock signal wires extending towards the gates, and wherein first adjacent pairs of said rows are n-type and second adjacent pairs of said rows are p-type.

22. The design structure of claim 21, wherein the backside clock signal wires are located between corresponding ones of the n-type rows and the p-type rows.

23. The design structure of claim 22, wherein the backside power connections and backside power rails are located between pairs of the n-type rows and between pairs of the p-type rows.

24. The design structure of claim 19, wherein:
the channels comprise nanosheet channel regions; and
the gates comprise all-around gates.

25. The design structure of claim 19, further comprising:
a first signal source coupled to the plurality of backside signal wires;
a second signal source coupled to the plurality of frontside signal lines; and
a power supply coupled to the plurality of backside power rails.
